(19) United States
(12) Patent Application Publication
(10) Pub. No.: US 2026/0301833 A1
(43) Pub. Date: Oct. 1, 2026

(54) MEMORY DEVICE, MEMORY DEVICE INCLUDING MEMORY DIE STACK, AND WAFER-LEVEL TESTING METHOD FOR SEMICONDUCTOR CHIP

(71) Applicant: SAMSUNG ELECTRONICS CO., LTD., Suwon-si (KR)

(72) Inventors: Yongmin KIM, Suwon-si (KR); Joohwan KIM, Suwon-si (KR); Seungjun BAE, Suwon-si (KR); Changhyun BAE, Suwon-si (KR); Jinwook LEE, Suwon-si (KR); Daihyun LIM, Suwon-si (KR); Kyungsoo HA, Suwon-si (KR)

(73) Assignee: SAMSUNG ELECTRONICS CO., LTD., Suwon-si (KR)

(21) Appl. No.: 19/413,244

(22) Filed: Dec. 9, 2025

(30) Foreign Application Priority Data
Mar. 25, 2025 (KR) 10-2025-0038335
Jun. 24, 2025 (KR) 10-2025-0083857

(51) Int. Cl. G11C 29/02; G11C 29/00

(52) U.S. Cl. CPC G11C 29/023; G11C 29/006; G11C 29/022; G11C 29/028

(57) ABSTRACT

A memory device includes an input/output (IO) module including a write clock path and a read clock path and an IO built-in self-test (IO BIST) device. The IO BIST device is configured to, in a wafer-level test of the memory device, monitor a clock skew of each of the write clock path and the read clock path and calibrate a corresponding clock skew based on a monitoring result.

### CROSS-REFERENCE TO RELATED APPLICATION

This application is based on and claims priority under 35 U.S.C. § 119 to Korean Patent Application Nos. 10-2025-0038335, filed on Mar. 25, 2025, and 10-2025-0083857, filed on Jun. 24, 2025, in the Korean Intellectual Property Office, the disclosures of which are incorporated by reference herein in their entirety.

### BACKGROUND

The present disclosure relates to a memory device, and more particularly, to a memory device including a memory die stack and a wafer-level testing method for semiconductor chips.

Recently, the needs for a processing speed of memory interfaces increase progressively, the frequency of a clock used in interfaces is increasing in speed. In such a high-speed operation environment, a phase skew between clock signals appears more remarkably, and due to this, a reduction in input/output (IO) margin occurs, and the reliability of the entire system is reduced. Therefore, technology for minimizing a phase skew between clock signals is required.

In the related art, a method has been generally used where the presence of defects and an IO margin based on a phase skew are evaluated and corrected after a package assembly is completed, namely, in the final product step. However, because such a method may determine the presence of defects after a package assembly, there is a limitation in early improving an IO margin or determining a defective sample.

### SUMMARY

The present disclosure provides a memory device which may effectively improve a clock skew for each clock path in a wafer-level test (for example, electrical die sorting (EDS), chip on wafer (CoW), or system in package (SiP)) step before a package assembly.

A memory device according to an embodiment includes a memory cell array, an input/output (IO) module including a write clock path and a read clock path, and an IO built-in self-test (BIST) (IO BIST) device, wherein the IO BIST device is configured to, in a wafer-level test of the memory device, monitor a clock skew of each of the write clock path and the read clock path and calibrate a corresponding clock skew, based on a monitoring result.

A memory device according to an embodiment includes a base die including a plurality of per-channel input/output (IO) modules, wherein each of the plurality of per-channel IO modules includes a plurality of DWORD modules, a first DWORD module among the plurality of DWORD modules includes an IO module including a write clock path and a read clock path for a memory cell array and an IO built-in self-test (BIST) (IO BIST) device, and the IO BIST device is configured to, in a wafer-level test of a memory die including the first DWORD module, monitor a clock skew of each of the write clock path and the read clock path and calibrate a corresponding clock skew, based on a monitoring result.

A wafer-level testing method for semiconductor chip, according to an embodiment, includes receiving a start signal of a timing margin measurement test (TMMT) from a test module and monitoring, by using an input/output built-in self-test (IO BIST) device included in a target wafer of the semiconductor chip, a clock skew of each of a write clock path and a read clock path, calibrating a corresponding clock skew, based on a monitoring result, and outputting a digital code corresponding to a final monitoring result, in response to the start signal.

### BRIEF DESCRIPTION OF THE DRAWINGS

Embodiments will be more clearly understood from the following detailed description taken in conjunction with the accompanying drawings in which:

FIG. 1 is a block diagram for describing a semiconductor device according to an embodiment;

FIG. 2 is a block diagram for describing a memory device of FIG. 1 according to embodiments;

FIG. 3 is a block diagram for describing a DWORD module of FIG. 2 according to embodiments;

FIG. 4 is a diagram for describing an enhanced wafer yield according to embodiments;

FIG. 5 is a block diagram for describing the DWORD module of FIG. 2 according to embodiments, in an operation viewpoint after packaging (for example, after release);

FIG. 6 is a block diagram for describing an IO BIST device of FIG. 3 according to embodiments;

FIG. 7 is a diagram for describing an example where TMMT is performed in a wafer-level test, according to an implementation embodiment of the present disclosure;

FIG. 8 is a block diagram for describing an implementation embodiment of a read clock path skew monitoring module of FIGS. 6 and 7;

FIG. 9 is a block diagram for describing an implementation embodiment of a write clock path skew monitoring module of FIGS. 6 and 7;

FIG. 10 is a timing diagram of comparators of FIGS. 8 and 9 according to an embodiment;

FIG. 11 is a flowchart illustrating an operating method of a memory device, according to an embodiment; and

FIGS. 12 to 14 are diagrams illustrating examples of a semiconductor package according to embodiments.

### DETAILED DESCRIPTION OF THE EMBODIMENTS

First, “each of modules” described herein may correspond to hardware, software, or a combination thereof, which is included in a computing system. Hardware may include at least one of a programmable component such as a central processing unit (CPU), a digital signal processor (DSP), and a graphics processing unit (GPU), a reconfigurable component such as a field programmable gate array (FPGA), and a component, providing a stationary function, such as an intellectual property (IP) block. Software may include at least one of a series of instructions executable by a programmable component and code capable of being converted into a series of instructions by a compiler or the like.

Hereinafter, embodiments will be described in detail with reference to the accompanying drawings.

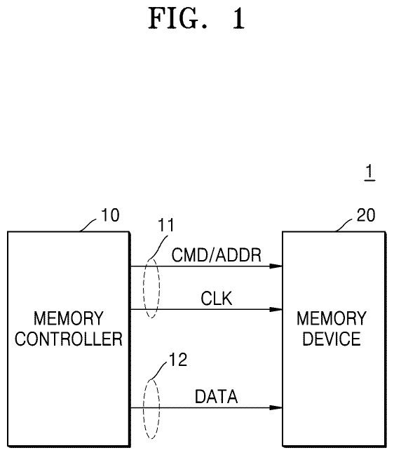

FIG. 1 is a block diagram for describing a semiconductor device 1 according to an embodiment.

Referring to FIG. 1, the semiconductor device 1 according to an embodiment may include a memory controller 10 and a memory device 20.

Each of the memory controller 10 and the memory device 20 may include an interface for communication therebetween. The interfaces may be connected to each other through a control bus 11 for transferring a command CMD, an address ADDR, and a clock CLK signal and a data bus 12 for transferring data. The command CMD may be transferred along with the address ADDR. The memory controller 10, for example, may provide a read command, a write command, a refresh command, and a mode register setting command to the memory device 20.

The memory controller 10 may generate the command CMD for controlling the memory device 20, and based on control by the memory controller 10, data DATA may be written in the memory device 20, or may be read from the memory device 20.

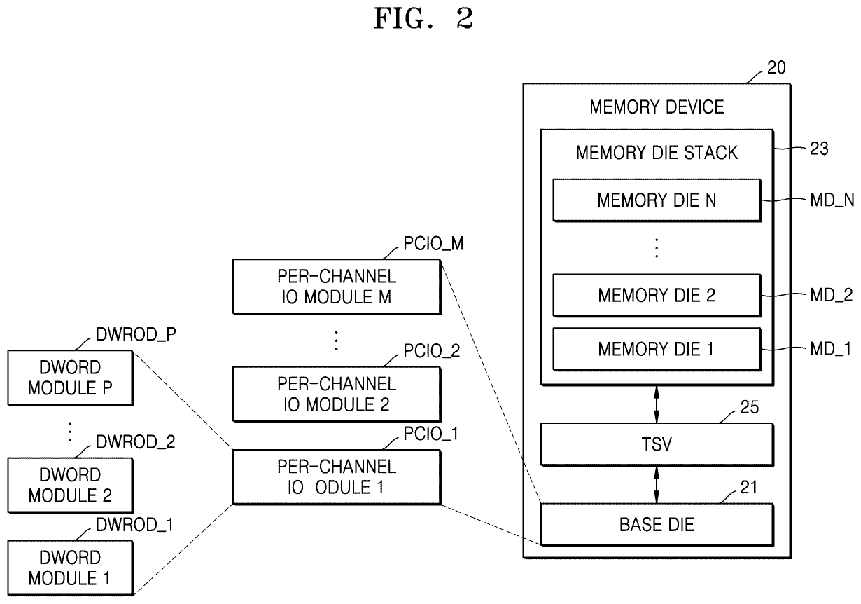

FIG. 2 is a block diagram for describing the memory device 20 of FIG. 1 according to embodiments.

Referring to FIG. 2, the memory device 20 may include a plurality of channels each including an independent interface, and thus, may have a structure where a bandwidth increases. That is, the memory device 20 may be implemented as a high bandwidth memory (HBM).

Referring to FIG. 2, the memory device 20 may include a base die 21 and a memory die stack 23. That is, the memory device 20 may include the memory die stack 23 which is stacked on the base die 21.

In some embodiments, the base die 21 may be referred to as a buffer die, a bottom die, or a logic die and may include a main control logic or an interface circuit.

The memory die stack 23 may include a memory die 1 MD_1 to a memory die N MD_N (where N may be a natural number of 1 or more), and each of the memory die 1 MD_1 to memory die N MD_N may be referred to as a core die. For example, the number of core dies N may be 2, 4, 8, or 16 and may be variously changed based on the version of an HBM.

A plurality of channels may be allocated to the base die 21. Also, the base die 21 may include a channel-based input/output module 1 (hereinafter referred to as a per-channel IO module) PCIO_1 to a per-channel IO module M PCIO_M (where M may be a natural number of 1 or more). Here, each per-channel IO module may denote an IO circuit or an IO region corresponding to one channel in the base die 21.

Each channel may include a plurality of PHY channels. Also, each per-channel IO module may include a DWORD module 1 DWORD_1 to a DWORD module P DWORD_P (where P may be a natural number of 1 or more). Here, the DWORD module may denote an IO circuit or an IO region corresponding to one PHY channel in one channel. In some embodiments, the DWORD module may be an IO circuit or an IO region, which performs processing of data of a 32-bit unit corresponding to one PHY channel in one channel. That is, a per-channel IO module may manage all of one channel, and the DWORD module may be a detailed block which processes data of PHY channel unit (for example, 32 bits) in one channel.

For example, in a case where the number of channels is 32, each channel consists of two PHY channels PC0 and PC1, and each PHY channel processes 32-bit data, the memory device 20 may support an input/output of data of total 2,048 bits.

Also, referring to FIG. 2, in some embodiments, the memory device 20 may further include a through silicon via (TSV) 25. The TSV 25 may have a structure for an electrical connection between an upper chip and a lower chip and may electrically connect the memory die stack 23 to the base die 21.

For example, the TSV 25 may be a conductive via vertically passing through silicon substrates (for example, the upper chip and the lower chip), and the memory device 20 may be a stack-type memory device which includes the base die 21, the memory die stack 23, and the TSV 25. That is, the memory device 20 may be a device where the base die 21, the TSV 25, and the memory die stack 23 are stacked and packaged. Here, the base die 21 and the memory die stack 23 may be electrically connected to each other by the TSV 25.

The base die 21 may communicate with the memory controller 10. Each of the memory die 1 MD_1 to memory die N MD_N may be implemented as dynamic random access memory (DRAM) such as double data rate synchronous dynamic random access memory (DDR SDRAM), low power double data rate (LPDDR) SDRAM, graphics double data rate (GDDR) SDRAM, or Rambus dynamic random access memory (RDRAM), which includes a plurality of dynamic memory cells.

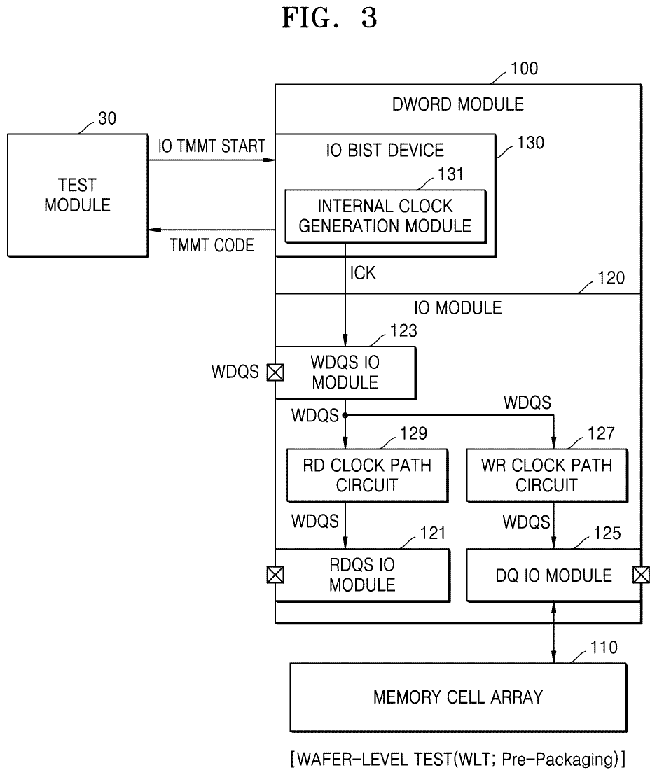

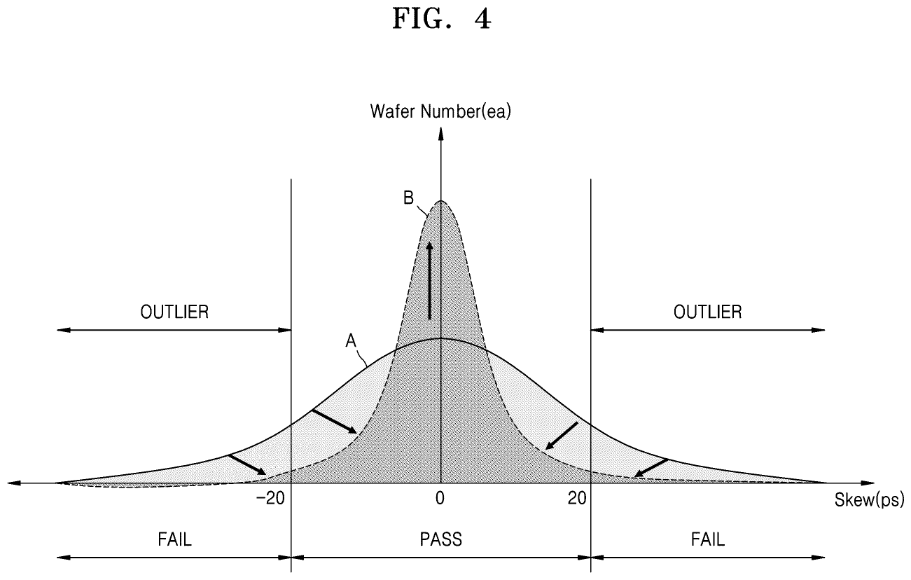

FIG. 3 is a block diagram for describing the DWORD module of FIG. 2 according to embodiments. FIG. 4 is a diagram for describing an enhanced wafer yield according to embodiments. A DWORD module 100 may correspond to one of the DWORD module 1 DWORD_1 to DWORD module P DWORD_P of FIG. 2.

Referring to FIG. 3, the DWORD module 100 may include an input/output module (hereinafter referred to as an IO module) 120 corresponding to the memory cell array 110 and an IO built-in self-test (BIST) (IO BIST) device 130. Here, the DWORD module 100 may correspond to the memory cell array 110 included in one memory die of the memory die stack 23 and may support an input/output of the memory cell array 110.

That is, the DWORD module 100 according to an embodiment may further include the IO BIST device 130, and thus, may provide an additional test function in a wafer-level test.

The IO BIST device 130 may be a built-in self-test (BIST) device and may additionally perform an IO timing margin measurement test (TMMT) on an IO module 120 of the DWORD module 100 in a wafer-level test before packaging of a memory die.

Here, the TMMT may denote a test process which measures the timing margin of a DQ signal, a WDQS signal, and/or an RDQS signal in an IO path of a memory device. The TMMT may measure a signal skew and a timing mismatch, which may occur due to a process variation, a TSV length difference, or in-chip wiring non-uniformity, and may be performed for generating reference data for calibrating the signal skew and the timing mismatch. For example, in a wafer-level test, the TMMT according to an embodiment may quantify a timing margin and a skew which are in a write clock path and/or a read clock path, based on an internal clock ICK. Information about the measured timing margin or skew may be output as a TMMT code (TMMT CODE), and the TMMT code (TMMT CODE) may be intactly stored or may be modified and stored in a fuse memory and may be used as a criterion for timing calibration at the initialization time of the memory device 20.

That is, according to an embodiment, the TMMT code (TMMT CODE) may include calibration information about a duty cycle of the internal clock ICK, calibration information about a clock skew of the read clock path, or calibration information about a clock skew of the write clock path.

Referring to FIG. 3, the IO BIST device 130 may include an internal clock generation module 131, and the internal clock generation module 131 may generate the internal clock ICK and may provide the internal clock ICK to the IO module 120.

Referring to FIG. 3, in a wafer-level test, the DWORD module 100 may perform an IO TMMT in response to a signal (IO TMMT START) of a test module 30, and the IO BIST device 130 may output the TMMT code (TMMT CODE) as a performance result of the IO TMMT. Here, in response to the signal (IO TMMT START) of the test module 30, the internal clock generation module 131 may generate the internal clock ICK and may provide the internal clock ICK to the IO module 120.

As described above, according to some embodiments, based on only a single start signal (for example, the signal (IO TMMT START)), the DWORD module 100 may implement auto/self calibration which performs the TMMT to calculate a performance result.

Also, the TMMT code (TMMT CODE) may be information about a skew of a certain signal and may be used in a fuse operation later. Here, the certain signal may include, for example, at least one of an output signal of the internal clock generation module 131 for TMMT, an output signal of the write clock path circuit 127, and an output signal of the read clock path circuit 129.

A fuse operation will be described below in more detail. A timing calibration value determined based on the TMMT code (TMMT CODE) may be stored in a fuse, and then, when initializing the memory device 20, a timing characteristic of an IO path may be adjusted with reference to a corresponding fuse value. Here, the fuse may be coded through a non-volatile scheme, and such coding may be referred to as a fuse operation. The fuse operation may be performed in a test process before a product is released or a trimming process after packaging, and in this process, the timing calibration value based on the TMMT code (TMMT CODE) may be previously stored in the fuse. For example, a skew calibration value detected in a WDQS, RDQS, or DQ path of each DWORD module may be stored in a corresponding fuse bit, and at an operation time of the memory device 20, a timing corrected in a delay locked loop (DLL), a re-timer circuit, or an input timing control circuit may be applied based on the skew calibration value. Such a fuse-based timing calibration method may calibrate the non-uniformity of an IO timing occurring due to a process variation or a TSV path difference and may thus contribute to enhance the reliability and data transfer stability of an entire system.

Referring again to FIG. 3, the IO module 120 may include an RDQS IO module 121 including an RDQS pin, a WDQS IO module 123 including a WDQS pin, a DQ IO module 125 including a DQ pin, a write clock path circuit 127, and a read clock path circuit 129. Here, the RDQS pin may be a pin which outputs an RDQS signal, and the RDQS signal may denote a timing reference signal of read data DATA_R. The WDQS pin may be a pin which receives a WDQS signal, and the WDQS signal may denote a timing reference signal of write data DATA_W. The DQ pin may be a pin which inputs or outputs a DQ signal, and the DQ signal may denote the read data DATA_R or the write data DATA_W. Also, each IO module may include a circuit which includes a buffer circuit and a transmission/reception driver for an input/output of a corresponding signal.

The write clock path circuit 127 may denote circuits which are disposed between the WDQS IO module 123 and the DQ IO module 125 and configure a path which relays a WDQS signal. For example, when the WDQS signal is received by the WDQS pin of the WDQS IO module 123, the WDQS signal may be transferred to the DQ IO module 125 through the write clock path circuit 123 and may be used as a timing criterion which is used to sample write data DATA_W.

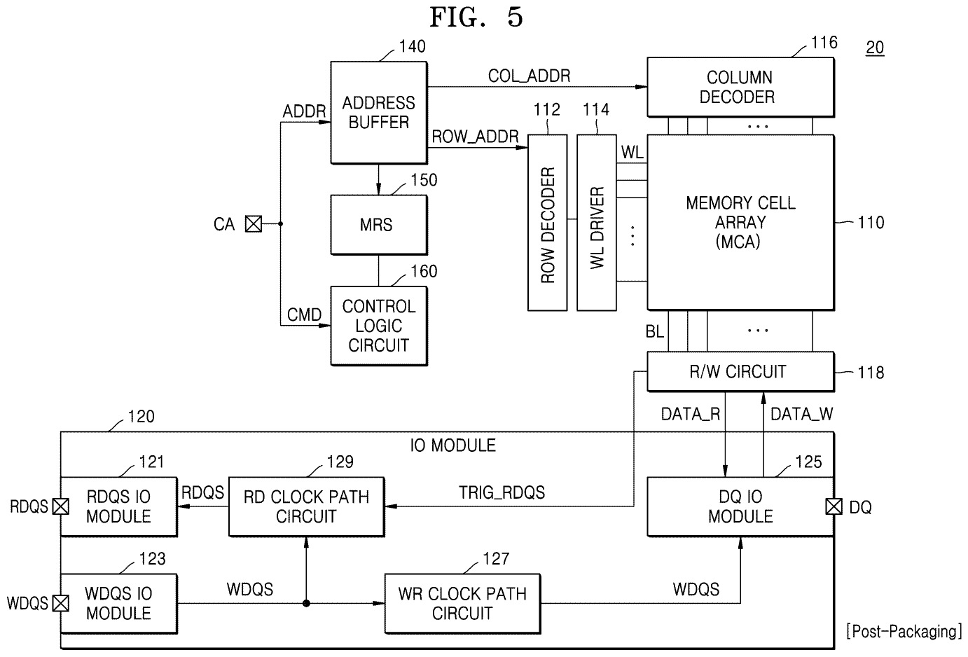

Also, the read clock path circuit 129 may denote circuits configuring a path which relays the RDQS signal, generated in the DWORD module 100, to the RDQS IO module 121 (see FIG. 5). For example, when a read operation is triggered in the DWORD module 100, the read clock path circuit 129 may transfer the RDQS signal to the RDQS IO module 121, and thus, the RDQS pin may output the RDQS signal, thereby providing a timing criterion of the read data DATA_R to an external device (for example, a host, etc.).

The write clock path circuit 127 and/or the read clock path circuit 129 may be configured with, for example, various circuit elements such as a repeater, a buffer, a multiplexer, a demultiplexer, a delay element, and/or a level shifter.

Furthermore, in a wafer-level test, the RDQS IO module 121 and the WDQS IO module 123 may not yet be electrically connected to a TSV (25 of FIG. 2) (i.e., before packaging), and thus, the DWORD module 100 may not transfer or receive the RDQS signal or the WDQS signal to or from the memory die stack 23 or the TSV 25.

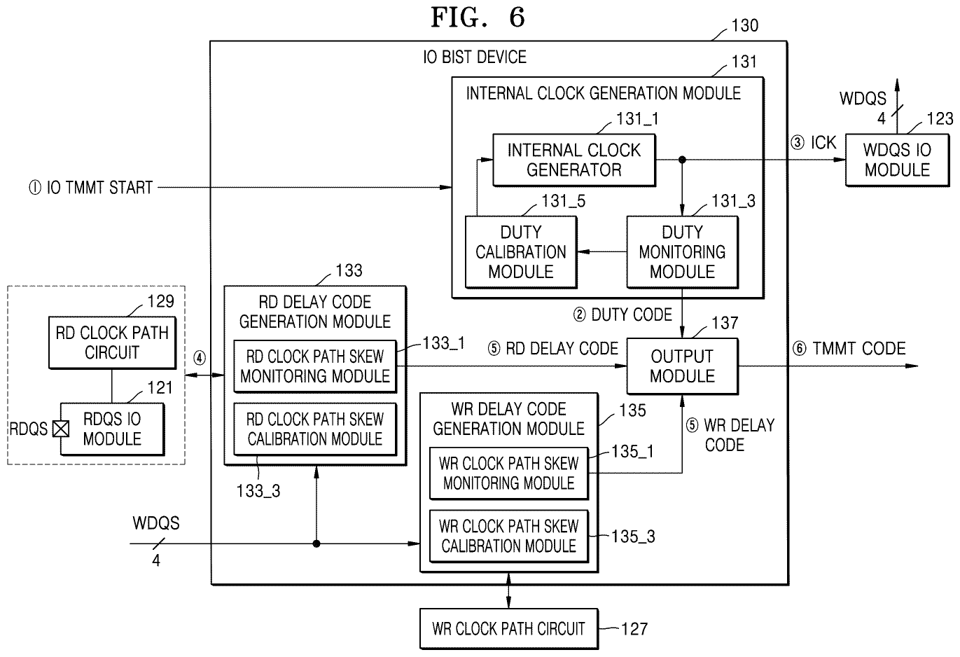

According to an embodiment, in a wafer-level test, the internal clock generation module 131 included in the IO BIST device 130 may provide the internal clock ICK to the WDQS IO module 123, and thus, the WDQS IO module 123 may autonomously generate the WDQS signal and may perform a TMMT on an output signal of the write clock path circuit 127 and an output signal of the read clock path circuit 129, based on the generated WDQS signal. This will be described below in detail with reference to FIGS. 6 to 11.

The IO BIST device 130 may provide the WDQS IO module 123 with the internal clock ICK generated in the internal clock generation module 131 in a wafer-level test, and thus, the internal clock ICK may be transferred to the DQ IO module 125 via the write clock path circuit 127 (or may be transferred to the read clock path circuit 129) and may simulate an environment similar to a real write operation (or read operation) when performing a TMMT.

That is, the DWORD module 100 according to an embodiment may include the IO BIST device 130 including the internal clock generation module 131, and thus, in a wafer test operation, a TMMT on a write clock path and/or a read clock path may be performed even without an external signal (for example, the WDQS signal, etc.). Here, the “wafer test operation” may correspond to at least one of tests of electrical die sorting (EDS), chip on wafer (CoW), and system in package (SiP) levels.

Accordingly, a defect of an IO interface may be early detected in a wafer test operation, and thus, a wafer yield may be enhanced.

FIG. 4 is a diagram illustrating a wafer distribution with respect to a skew of an RDQS signal. For example, by using the IO BIST device 130 according to an embodiment, as illustrated in FIG. 4, a skew distribution (a solid line A) of the RDQS signal may be improved into a distribution (a dashed line B). That is, the number of wafers having a skew of −20 ps or less or 20 ps or more may decrease, and the number of wafers having a skew of more than −20 ps or less than 20 ps may increase.

Accordingly, a wafer where a skew value is greater than a certain threshold value may be effectively screened out, and thus, the total wafer yield may increase.

Moreover, a ratio of defective wafers may decrease, and moreover, the time and cost of a post package test operation may be reduced, a yield of assembly process may increase, and the total manufacturing cost may be reduced.

For example, the IO BIST device 130 according to an embodiment may perform a function of a screen-out outlier device in an EDS-level test, a CoW-level test, or an SiP-level test.

As described above, the IO BIST device 130 according to an embodiment may automatize a TMMT in a wafer test operation, thereby enhancing the reliability and yield of the memory device 20 simultaneously.

According to an embodiment, a clock skew may be minimized through auto/self calibration which automatically operates based on a single start signal, and thus, an IO margin may be improved, and a reference point for detecting a defective sample in a wafer-level test may be provided simultaneously, thereby contributing to the enhancement of the total yield.

Moreover, according to an embodiment, a phase calibration operation and a defect detection operation each performed in a conventional package-level test may be screened out, thereby contributing to the reduction in package test time. Particularly, in a case where a plurality of memory dies are stacked like HBM, when a phase skew is capable of being improved in an operation before package assembly and stack assembly, an effect thereof may be more remarkable, and the present disclosure may be used even in an SiP-level test after package assembly.

FIG. 5 is a block diagram for describing the DWORD module of FIG. 2 according to embodiments, in an operation viewpoint after packaging (for example, after release).

To help understand an embodiment, the DWORD module 100 of FIG. 2 after packaging is completed may be described with reference to FIG. 5. In FIG. 5, the DWORD module 100 of FIG. 3 may correspond to an IO module 120.

Referring to FIG. 5, a memory device 20 corresponding to the DWORD module 100 (or the IO module 120) may include a memory cell array 110, a row decoder 112, a word line driver 114, a column decoder 116, a read/write circuit 118, an IO module 120, an address buffer 140, a mode register set (MRS) 150, and a control logic circuit 160. Here, in some embodiments, the control logic circuit 160, the address buffer 140, and the MRS 150 may be shared by another DWORD module of the same memory die. That is, the control logic circuit 160, the address buffer 140, and the MRS 150 may be shared by channel or memory die units.

The memory cell array 110 may include a plurality of memory cells which are provided in a matrix form arranged in rows and columns. The memory cell array 110 may include a plurality of word lines WL and a plurality of bit lines BL, which are connected to the memory cells. The plurality of word lines WL may be connected to rows of memory cells, and the plurality of bit lines BL may be connected to columns of memory cells.

The row decoder 112 may select one word line WL from among the plurality of word lines WL connected to the memory cell array 110. The row decoder 112 may decode a row address ROW_ADDR received through a command/address bus CA and an address buffer 140 to select one word line WL corresponding to the row address ROW_ADDR and may be connected to the word line driver 114 which activates the selected word line WL. The column decoder 116 may select certain bit lines BL from among the plurality of bit lines BL of the memory cell array 110. The column decoder 116 may decode a column address COL_ADDR received from the address buffer 140 to generate a column selection signal and may connect bit lines BL, selected by the column selection signal, to the read/write circuit 118.

The read/write circuit 118 may be a circuit for reading or writing data of the memory cell array 110 and may include a sense amplifier SA which senses the voltage difference sensed from a memory cell and amplifies the voltage difference at a logic level, a read data latch which stores read data DATA_R of the bit lines BL selected by the column selection signal, and a write driver for writing write data DATA_W in the memory cell array 110.

The read data DATA_R stored in the read data latches of the read/write circuit 118 may be output from the DQ pin through a data output driver of the DQ IO module 125. The write data DATA_W may be sampled in a data input buffer of the DQ IO module 125 in synchronization with the WDQS signal, and thus, may be provided to the read/write circuit 118 and may be applied to the memory cell array 110 through the write driver of the read/write circuit 118.

The IO module 120 may include an RDQS IO module 121 including an RDQS pin, a WDQS IO module 123 including a WDQS pin, a DQ IO module 125 including a DQ pin, a write clock path circuit 127, and a read clock path circuit 129. In some embodiments, unlike that shown in FIG. 5, the IO module 120 may further include an RDQS generation module.

The RDQS IO module 121 may be a circuit which outputs a read data strobe (RDQS) signal which is a timing criterion when reading data in the DWORD module 100 and may output the generated RDQS through the RDQS pin along with the read data DATA_R output from the DQ pin, in synchronization with an internal or external clock.

The WDQS IO module 123 may be a circuit which processes a write data strobe (WDQS) signal which is a timing criterion when writing data and may transfer the WDQS signal, received through the WDQS pin, to an internal circuit to allow a valid timing of the DQ signal (the write data DATA_W) to be aligned.

The DQ IO module 125 may be a path through which data is substantially input or output and may include a plurality of DQ pins, and each of the plurality of DQ pins may transfer or receive the DQ signal. Also, the DQ IO module 125 may include the data output driver and the data input buffer.

The data output driver may be a circuit for outputting, to the outside, the read data DATA_R transferred from an internal circuit (for example, the read/write circuit 118) and may provide sufficient drive capability, based on a capacitive load of the DQ pin, thereby guaranteeing high-speed signal transmission and signal integrity.

The data input buffer may be a circuit for stably receiving the write data DATA_W received from the outside and transferring the write data DATA_W to an internal circuit, and moreover, may sense a voltage swing of an input signal to convert the input signal into an internal logic level, may secure a noise margin, and may perform a timing align function. Particularly, the data input buffer may operate as a timing control circuit which is synchronized with the WDQS signal, and thus, may support write data to be sampled at an accurate clock edge. That is, the data input buffer may convert the write data DATA_W, input from the outside, into an internal circuit level to transfer sampled data to the DWORD module 100, and for example, may sample the write data DATA_W to transfer sampled data to the read/write circuit 118, in synchronization with the WDQS signal.

Each IO module may include a precise synchronization function and an electrical calibration function so as to secure a timing margin and interface quality between a memory block and the outside and may be used as a path for performing a BIST or a TMMT in a test mode.

The write clock path circuit 127 may include circuits which are disposed between the WDQS IO module 123 and the DQ IO module 125 and configure a path which relays a WDQS signal. For example, when the WDQS signal is received by the WDQS pin of the WDQS IO module 123, the WDQS signal may be transferred to the DQ IO module 125 through the write clock path circuit 123 and may be used as a timing criterion which is used to sample write data DATA_W.

Also, the read clock path circuit 129 may include circuits configuring a path which relays the RDQS signal, generated in the DWORD module 100, to the RDQS IO module 121. For example, when a read operation is triggered in the DWORD module 100, the read clock path circuit 129 may transfer the RDQS signal to the RDQS IO module 121, and thus, the RDQS pin may output the RDQS signal, thereby providing a timing criterion of the read data DATA_R to an external device (for example, a host, etc.).

For example, referring to FIG. 5, in response to a trigger signal TRIG_RDQS of the read/write circuit 118, the read clock path circuit 129 may generate the RDQS signal and may provide the RDQS signal to the RDQS IO module 121, based on the WDQS signal input through the WDQS IO module 123. That is, the read clock path circuit 129 may generate an internal RDQS signal with reference to phase information about the WDQS signal input in a read operation and may provide the generated RDQS signal to the RDQS IO module 121. However, the present disclosure is not limited thereto, and a separate RDQS generation module may generate the RDQS signal in response to the trigger signal TRIG_RDQS of the read/write circuit 118, and the read clock path circuit 129 may relay a corresponding RDQS signal to the RDQS IO module 121.

Also, according to an embodiment, each of the write clock path circuit 127 and the read clock path circuit 129 may be used as a target path of a TMMT by the IO BIST device 120 in a wafer test operation. At this time, the TMMT may be performed based on the internal clock ICK generated from the internal clock generation module 131, and as a result, the TMMT code (TMMT CODE) may be generated and used as fuse information.

Hereinafter, a read clock path may denote a path up to the RDQS pin of the RDQS IO module 121 from the read clock path circuit 129 which relays the RDQS signal, and a write clock path may denote the write clock path circuit 127 which relays the WDQS signal.

The control logic circuit 160 may receive a command CMD through the command/address pin CA and may generate control signals which control a memory operation and/or an operation timing of the DWORD module 100. The control logic circuit 160 may read data from the memory cell array 110 by using the control signals and may write the data in the memory cell array 110.

The MRS 150 may store information used by the control logic circuit 160 to configure operations of the DWORD module 100, so as to set an operation condition of the DWORD module 100. The MRS 150 may include a register which stores a parameter code corresponding to a control parameter and various operations used to set the operation condition of the DWORD module 100. The parameter code may be received by the DWORD module 100 through the command/address pin CA.

The control logic circuit 160 may generate control signals provided to circuits of the DWORD module 100 so as to operate like being set in the control parameter and operation stored in the MRS 150.

Furthermore, in a wafer-level test, the RDQS IO module 121 and the WDQS IO module 123 may not yet be electrically connected to the TSV 25 (i.e., before packaging), and thus, the DWORD module 100 may not transfer or receive the RDQS signal or the WDQS signal to or from the memory die stack 23 or the TSV 25.

According to an embodiment, in a wafer-level test, the internal clock generation module 131 included in the IO BIST device 130 may provide the internal clock ICK to the WDQS IO module 123, and thus, the WDQS IO module 123 may autonomously generate the WDQS signal and may perform a TMMT on an output signal of the write clock path circuit 127 and an output signal of the read clock path circuit 129, based on the generated WDQS signal. Hereinafter, this will be described in detail.

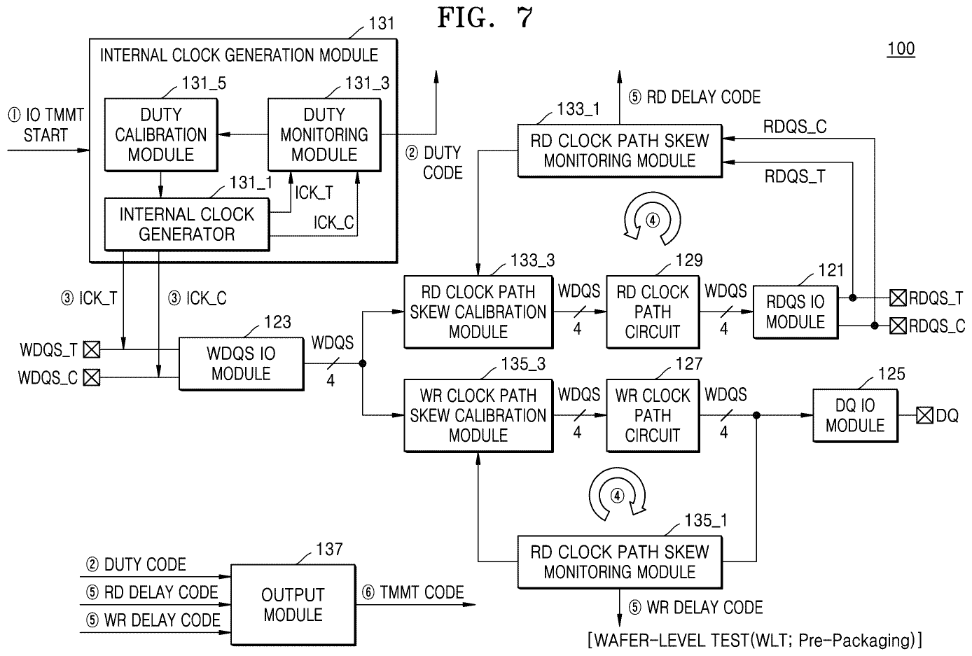

FIG. 6 is a block diagram for describing the IO BIST device 130 of FIG. 3 according to embodiments. FIG. 7 is a diagram for describing an example where a TMMT is performed in a wafer-level test, according to an implementation embodiment of the present disclosure.

Referring to FIG. 6, an IO BIST device 130 may include an internal clock generation module 131, a read delay code generation module 133, a write delay code generation module 135, and an output module 137.

In response to the signal (IO TMMT START) of a test module 30, the internal clock generation module 131 may generate an internal clock ICK and may provide the internal clock ICK to a WDQS IO module 123. Here, before the internal clock ICK is provided to the WDQS IO module 123, the internal clock generation module 131 may adjust a duty ratio of the internal clock ICK through a feedback loop. Also, the internal clock generation module 131 may provide the output module 137 with finally-adjusted duty information in the form of duty code (DUTY CODE).

That is, the internal clock generation module 131 may generate the internal clock ICK used in a wafer test operation and may perform a function of correcting and checking the quality of the generated internal clock ICK.

Referring to FIG. 6, the internal clock generation module 131 may include an internal clock generator 131_1, a duty monitoring module 131_3, and a duty calibration module 131_5.

The internal clock generator 131_1 may generate the internal clock ICK, and for example, may be implemented as a clock generation circuit such as a digital clock manager (DCM), a ring oscillator, a DLL, or a phase locked loop (PLL). The internal clock ICK output from the internal clock generator 131_1 may be provided to the duty monitoring module 131_3.

The duty monitoring module 131_3 may monitor a duty of the internal clock ICK, based on the internal clock ICK. That is, the duty monitoring module 131_3 may measure and analyze a duty ratio of the internal clock ICK. The duty monitoring module 131_3 may precisely measure the duration of a logic high state or a logic low state of the internal clock ICK to determine a real duty ratio and may provide a monitoring result to the duty calibration module 131_5. Here, a duty ratio may denote a ratio where the internal clock ICK is maintained in a logic high state or a logic low state.

The duty calibration module 131_5 may control the internal clock generator 131_1 so that a duty ratio of the internal clock ICK is approximately to 50:50, based on the monitoring result. For example, the duty calibration module 131_5 may adjust an operation parameter (for example, a delay time, a phase information value, etc.) of the internal clock generator 131_1, based on the monitoring result (for example, duty measurement information), and thus, may calibrate a duty ratio of the internal clock ICK to approximately be 50:50.

A calibration loop described above may have a feedback loop structure and may be repeatedly performed so that a duty ratio reaches a predetermined threshold range (for example, 50%±2%, etc.). Whether a criterion is satisfied may be determined by an output of the duty monitoring module 131_3, and when a duty ratio satisfies a threshold range, the internal clock generator 131_1 may provide a finally-calibrated internal clock ICK to the WDQS IO module 123.

Also, the duty monitoring module 131_3 may provide the output module 137 with a monitoring result (for example, duty measurement information) at a duty calibration completion time on the internal clock ICK in the form of duty code (DUTY CODE). In some embodiments, the duty code (DUTY CODE) may be a digital code representing a calibrated duty value and may consist of a certain number of bits (for example, 4 bits).

Here, the duty code (DUTY CODE) may be a test result and may be used in subsequent system verification and calibration corresponding to an environment change (for example, a temperature change or a voltage variation) or timing calibration when initializing the DWORD module 100. That is, the duty code (DUTY CODE) may be data quantitatively representing a final calibration state of a duty ratio, and moreover, may provide useful reference information when calibrating a process, checking a chip characteristic, or selecting redundancy in manufacturing and may guarantee a high-reliability memory operation.

Moreover, such a process may be automatically triggered by an external signal (for example, a signal (IO TMMT START)), and thus, auto calibration may be performed without a separate manipulation of a user. This may provide an efficient timing margin measurement and calibration function in a wafer-level test and may contribute to increase the quality and reliability of products in massive production.

Also, in some embodiments, the internal clock ICK may be provided to the WDQS IO module 123 in the form of a differential clock. For example, referring to FIG. 7, the internal clock generator 131_1 may generate an internal clock ICK_T and an internal clock ICK_C as calibration-completed clock signals and may respectively apply the internal clock ICK_T and the internal clock ICK_C to a pin WDQS_T and a pin WDQS_C of the WDQS IO module 123. Here, the internal clock ICK_T and the internal clock ICK_C may be a differential signal pair and may have a relationship of phases opposite to each other.

Referring to FIG. 7, the WDQS IO module 123 may include the pin WDQS_T and the pin WDQS_C and may output a clock WDQS_I, a clock WDQS_Q, a clock WDQS_IB, and a clock WDQS_QB in the form of a four-phase clock, based on the internal clock ICK_T received through the pin WDQS_T and the internal clock ICK_C received through the pin WDQS_C, and the clock WDQS_I, the clock WDQS_Q, the clock WDQS_IB, and the clock WDQS_QB may respectively correspond to clocks having 0-degree, 90-degree, 180-degree, and 270-degree phases. The WDQS signal of FIG. 3 may correspond to the clock WDQS_I, the clock WDQS_Q, the clock WDQS_IB, and the clock WDQS_QB.

For example, the WDQS IO module 123 may generate four clocks (for example, the clock WDQS_I, the clock WDQS_Q, the clock WDQS_IB, and the clock WDQS_QB) from a differential input signal (for example, the internal clock ICK_T and the internal clock ICK_C) through a phase interpolation circuit or a phase shifting circuit.

Referring again to FIG. 6, the WDQS IO module 123 may provide the four clocks (for example, the clock WDQS_I, the clock WDQS_Q, the clock WDQS_IB, and the clock WDQS_QB) to a read delay code generation module 133 and a write delay code generation module 135.

The read delay code generation module 133 may apply the four clocks (for example, the clock WDQS_I, the clock WDQS_Q, the clock WDQS_IB, and the clock WDQS_QB) as an input signal to the read clock path circuit 129 and may monitor a skew of an output signal corresponding to a path up to the pin RDQS of the RDQS IO module 121 from the read clock path circuit 129 which is a relay path of the RDQS signal. Moreover, the read delay code generation module 133 may calibrate a skew of a corresponding output signal through a feedback loop, based on a monitoring result. Moreover, the read delay code generation module 133 may provide the output module 137 with skew calibration information about a finally-adjusted corresponding signal in the form of read delay code (RD DELAY CODE).

The write delay code generation module 135 may apply the four clocks (for example, the clock WDQS_I, the clock WDQS_Q, the clock WDQS_IB, and the clock WDQS_QB) as an input signal to the write clock path circuit 127 and may monitor a skew of an output signal corresponding to the write clock path circuit 127 which is a relay path of the WDQS signal. Moreover, the write delay code generation module 135 may calibrate a skew of a corresponding output signal through a feedback loop, based on a monitoring result. Moreover, the write delay code generation module 135 may provide the output module 137 with skew calibration information about a finally-adjusted corresponding signal in the form of write delay code (WR DELAY CODE).

Referring again to FIG. 6, the read delay code generation module 133 may include a read clock path skew monitoring module 133_1 and a read clock path skew calibration module 133_3. Also, the write delay code generation module 135 may include a write clock path skew monitoring module 135_1 and a write clock path skew calibration module 135_3. Each element will be described below with further reference to FIG. 7.

Referring to FIGS. 6 and 7, the read clock path skew calibration module 133_3 may receive the four clocks (for example, the clock WDQS_I, the clock WDQS_Q, the clock WDQS_IB, and the clock WDQS_QB) from the WDQS IO module 123 and may provide the four clocks (for example, the clock WDQS_I, the clock WDQS_Q, the clock WDQS_IB, and the clock WDQS_QB) to the read clock path circuit 129.

Also, based on a monitoring result of the read clock path skew monitoring module 133_1, the read clock path skew calibration module 133_3 may add a delay to each of the four clocks (for example, the clock WDQS_I, the clock WDQS_Q, the clock WDQS_IB, and the clock WDQS_QB). For example, the read clock path skew monitoring module 133_1 may be implemented as a delay cell. Here, the delay cell may finely adjust (late or early) an edge timing of each clock signal.

In this case, in some embodiments, delays respectively added to the clock WDQS_I, the clock WDQS_Q, the clock WDQS_IB, and the clock WDQS_QB may differ based on a monitoring result.

Referring to FIG. 7, the read clock path circuit 129 may provide the RDQS IO module 121 with the four clocks (for example, the clock WDQS_I, the clock WDQS_Q, the clock WDQS_IB, and the clock WDQS_QB). The RDQS IO module 121 may include a pin RDQS_T and a pin RDQS_C and may output a clock RDQS_T and a clock RDQS_C in the form of a two-phase clock, based on the four clocks (for example, the clock WDQS_I, the clock WDQS_Q, the clock WDQS_IB, and the clock WDQS_QB), the clock RDQS_T may be output from the pin RDQS_T, and the clock RDQS_C may be output from the pin RDQS_C. Here, the clock RDQS_T and the clock RDQS_C may be a differential signal pair and may have a relationship of phases opposite to each other.

The read clock path skew monitoring module 133_1 may receive the clock RDQS_T may be output from the pin RDQS_T and may receive the clock RDQS_C from the pin RDQS_C. The read clock path skew monitoring module 133_1 may monitor a skew of an output signal corresponding to a path up to the pin RDQS of the RDQS IO module 121 from the read clock path circuit 129 which is a relay path of the RDQS signal, based on the received clock RDQS_T and the received clock RDQS_C. Also, the read clock path skew monitoring module 133_1 may provide a monitoring result to the read clock path skew calibration module 133_3.

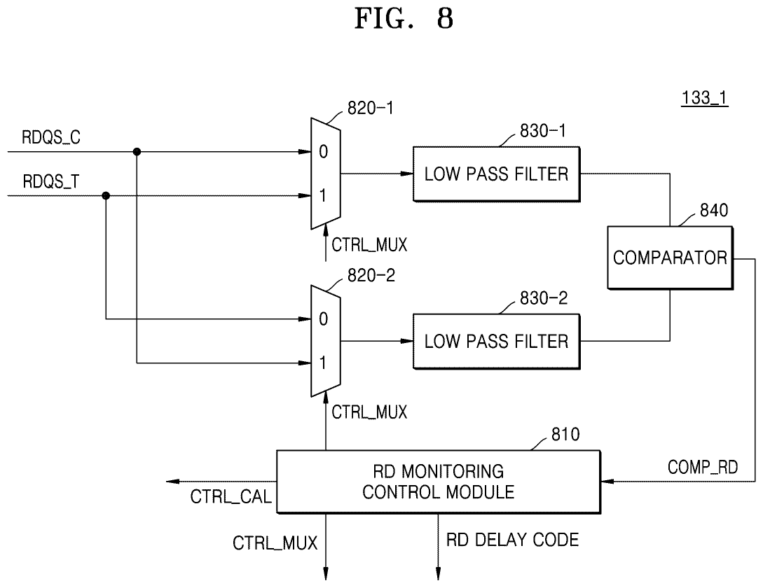

For example, the read clock path skew monitoring module 133_1 may measure an edge timing difference of each clock signal to sense a skew. An operation of monitoring a skew on the clock RDQS_T and the clock RDQS_C by using the read clock path skew monitoring module 133_1 will be described below in detail with reference to FIG. 8.

In some embodiments, an order in which a delay is added to clocks may be predetermined, and for example, the read clock path skew calibration module 133_3 may add a delay to each paired clocks in the order of a pair of clock WDQS_I and clock WDQS_IB, a pair of clock WDQS_Q and clock WDQS_QB, and a pair of clock WDQS_I and clock WDQS_Q. Such a method may sense an edge timing difference of each clock pair and may add a delay depending on the case, and thus, may minimize a skew, thereby contributing to increase signal integrity and an accuracy of data sampling.

Here, the RDQS IO module 121 may convert the four clocks WDQS_I, WDQS_Q, WDQS_IB, and WDQS_QB into two differential clocks RDQS_T and RDQS_C to output the differential clocks RDQS_T and RDQS_C, and thus, when seen from the outside, it may be seen that only a pair of clock RDQS_T and clock RDQS_C is to be monitored, but real skew calibration may be applied to a front end (i.e., four clocks in the read clock path skew calibration module 133_3) with respect to a signal path, whereby the four clocks WDQS_I, WDQS_Q, WDQS_IB, and WDQS_QB may be to be monitored.

A loop which adds a delay to each of the four clocks (for example, the clock WDQS_I, the clock WDQS_Q, the clock WDQS_IB, and the clock WDQS_QB) described above may be a feedback loop structure and may be repeatedly performed so that a monitoring result satisfies a predetermined condition (for example, when a skew measurement value is within a threshold value, or when a value obtained by converting a skew into a duty ratio is within the threshold value). Whether a criterion is satisfied may be determined by an output of the read clock path skew monitoring module 133_1, and when the monitoring result satisfies the predetermined condition, the read clock path skew monitoring module 133_1 may perform control so that the read clock path skew calibration module 133_3 does not any longer add a delay to the four clocks (for example, the clock WDQS_I, the clock WDQS_Q, the clock WDQS_IB, and the clock WDQS_QB). For example, the read clock path skew monitoring module 133_1 may provide the read clock path skew calibration module 133_3 with a control signal (CTRL_CAL of FIG. 8) which ends a delay adjustment loop.

Moreover, the read clock path skew monitoring module 133_1 may provide the output module 137 with a monitoring result (for example, skew calibration information) at a skew calibration completion time corresponding to an output signal of a relay path of the RDQS signal in the form of read delay code (RD DELAY CODE). In some embodiments, the read delay code (RD DELAY CODE) may be a digital code representing a duty value obtained by converting the skew calibration information and may consist of a certain number of bits (for example, 12 bits).

Here, the read duty code (RD DUTY CODE) may be a test result and may be used in subsequent system verification and calibration corresponding to an environment change (for example, a temperature change or a voltage variation) or timing calibration when initializing the DWORD module 100. That is, the read duty code (RD DUTY CODE) may be data quantitatively representing a final skew calibration state of the relay path of the RDQS signal, and moreover, may provide useful reference information when calibrating a process, checking a chip characteristic, or selecting redundancy in manufacturing and may guarantee a high-reliability memory operation.

Referring to FIGS. 6 and 7, the write clock path skew calibration module 135_3 may receive the four clocks (for example, the clock WDQS_I, the clock WDQS_Q, the clock WDQS_IB, and the clock WDQS_QB) from the WDQS IO module 123 and may provide the four clocks (for example, the clock WDQS_I, the clock WDQS_Q, the clock WDQS_IB, and the clock WDQS_QB) to the write clock path circuit 127.

Also, based on a monitoring result of the write clock path skew monitoring module 135_1, the write clock path skew calibration module 135_3 may add a delay to each of the four clocks (for example, the clock WDQS_I, the clock WDQS_Q, the clock WDQS_IB, and the clock WDQS_QB). For example, the write clock path skew monitoring module 135_1 may be implemented as a delay cell. Here, the delay cell may finely adjust (late or early) an edge timing of each clock signal.

In this case, in some embodiments, delays respectively added to the clock WDQS_I, the clock WDQS_Q, the clock WDQS_IB, and the clock WDQS_QB may differ based on a monitoring result.

Referring to FIG. 7, the write clock path circuit 127 may provide the DQ IO module 125 and the write clock path skew monitoring module 135_1 with the four clocks (for example, the clock WDQS_I, the clock WDQS_Q, the clock WDQS_IB, and the clock WDQS_QB).

The write clock path skew monitoring module 135_1 may monitor a skew of an output signal of the write clock path circuit 127 which is a relay path of the WDQS signal, based on the four clocks (for example, the clock WDQS_I, the clock WDQS_Q, the clock WDQS_IB, and the clock WDQS_QB) received. Also, the write clock path skew monitoring module 135_1 may provide a monitoring result to the write clock path skew calibration module 135_3.

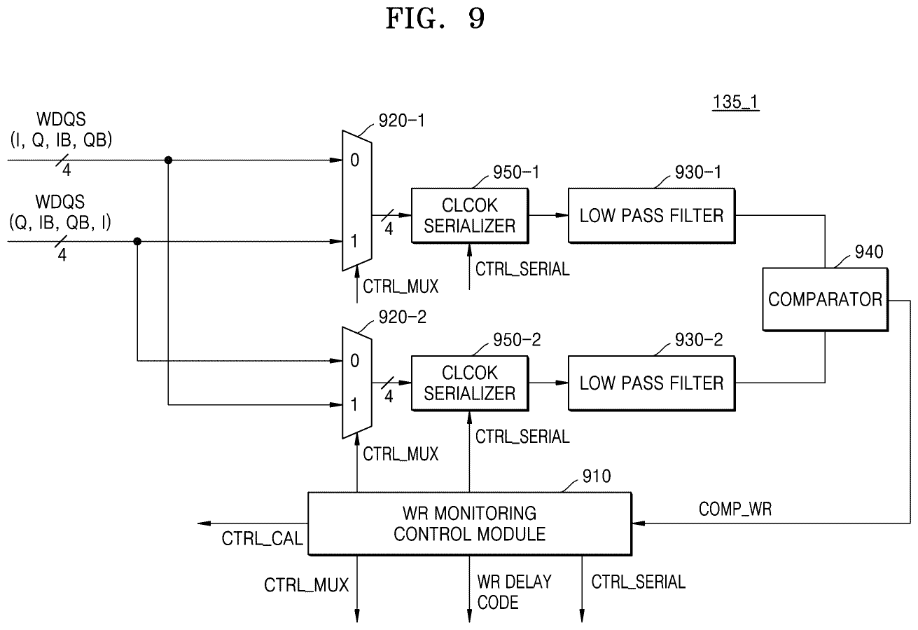

For example, the write clock path skew monitoring module 135_1 may measure an edge timing difference of each clock signal to sense a skew. An operation of monitoring a skew on the clock WDQS_I, the clock WDQS_Q, the clock WDQS_IB, and the clock WDQS_QB by using the write clock path skew monitoring module 135_1 will be described below in detail with reference to FIG. 9.

In some embodiments, a monitoring order (or an order in which a delay is added to clocks) may be predetermined, and for example, the write clock path skew monitoring module 135_1 may perform monitoring on each paired clocks in the order of a pair of clock WDQS_I and clock WDQS_IB, a pair of clock WDQS_Q and clock WDQS_QB, and a pair of clock WDQS_I and clock WDQS_Q, and thus, the write clock path skew calibration module 135_3 may also add a delay to each of corresponding two clocks in the same order. Such a method may sense an edge timing difference of each clock pair and may add a delay depending on the case, and thus, may minimize a skew, thereby contributing to increase signal integrity and an accuracy of data sampling.

A loop which adds a delay to each of the four clocks (for example, the clock WDQS_I, the clock WDQS_Q, the clock WDQS_IB, and the clock WDQS_QB) described above may be a feedback loop structure and may be repeatedly performed so that a monitoring result satisfies a predetermined condition (for example, when a skew measurement value is within a threshold value, or when a value obtained by converting a skew into a duty ratio is within the threshold value). Whether a criterion is satisfied may be determined by an output of the write clock path skew monitoring module 135_1, and when the monitoring result satisfies the predetermined condition, the write clock path skew monitoring module 135_1 may perform control so that the write clock path skew calibration module 135_3 does not any longer add a delay to the four clocks (for example, the clock WDQS_I, the clock WDQS_Q, the clock WDQS_IB, and the clock WDQS_QB). For example, the write clock path skew monitoring module 135_1 may provide the write clock path skew calibration module 135_3 with a control signal which ends a delay adjustment loop.

Moreover, the write clock path skew monitoring module 135_1 may provide the output module 137 with a monitoring result (for example, skew calibration information) at a skew calibration completion time corresponding to an output signal of a relay path of the WDQS signal in the form of write delay code (WR DELAY CODE). In some embodiments, the write delay code (WR DELAY CODE) may be a digital code representing a duty value obtained by converting the skew calibration information and may consist of a certain number of bits (for example, 12 bits).

Here, the write delay code (WR DELAY CODE) may be a test result and may be used in subsequent system verification and calibration corresponding to an environment change (for example, a temperature change or a voltage variation) or timing calibration when initializing the DWORD module 100. That is, the write delay code (WR DELAY CODE) may be data quantitatively representing a final skew calibration state of the relay path of the WDQS signal, and moreover, may provide useful reference information when calibrating a process, checking a chip characteristic, or selecting redundancy in manufacturing and may guarantee a high-reliability memory operation.

Moreover, a skew calibration operation on the output signal of the relay path of the RDQS signal described above and a skew calibration operation on the output signal of the relay path of the WDQS signal described above may be performed in parallel after a duty calibration operation on the internal clock ICK is completed.

Referring to FIGS. 6 and 7, the output module 137 may receive a duty code (DUTY CODE). Furthermore, when the output module 137 additionally receives the read delay code (RD DELAY CODE) and the write delay code (WR DELAY CODE), the output module 137 may group the duty code (DUTY CODE), the read delay code (RD DELAY CODE), and the write delay code (WR DELAY CODE), and thus, may output a TMMT code (TMMT CODE). For example, the output module 137 may output the TMMT code (TMMT CODE) to an external device (for example, the test module 30 of FIG. 3).

That is, the TMMT code (TMMT CODE) may represent a test result where the duty code (DUTY CODE), the read delay code (RD DELAY CODE), and the write delay code (WR DELAY CODE) are grouped.

In some embodiments, the TMMT code (TMMT CODE) may be a digital code representing the test result and may consist of a certain number of bits (for example, 28 bits). Moreover, in some embodiments, the output module 137 may be implemented as an IEEE 1500 logic circuit. Here, the IEEE 1500 logic circuit may denote a digital circuit which is implemented with a wrapper and a scan chain to independently test each core of a system on chip (SoC).

FIG. 8 is a block diagram for describing an implementation embodiment of the read clock path skew monitoring module of FIGS. 6 and 7.

Referring to FIG. 8, a read clock path skew monitoring module 133_1 may include a read monitoring control module 810, multiplexers 820-1 and 820-2, low pass filters 830-1 and 830-2, and a comparator 840.

Here, the read clock path skew monitoring module 133_1 may receive two differential signal pairs (for example a clock RDQS_T and a clock RDQS_C) as an input value, may output a control signal CTRL_CAL to a read clock path skew calibration module 133_3, based on a monitoring result (a signal COMP_RD), and may output a final monitoring result (a read delay code (RD DELAY CODE)) to an output module 137.

In response to a control signal CTRL_MUX, the multiplexers 820-1 and 820-2 and the low pass filters 830-1 and 830-2 may configure an unflip path, and an input signal of a corresponding path may be intactly input as original clocks (for example, a clock RDQS_T and a clock RDQS_C). On the other hand, in response to the control signal CTRL_MUX, the multiplexers 820-1 and 820-2 and the low pass filters 830-1 and 830-2 may configure a flip path, and an input signal of a corresponding path may be input to be opposite to the original clocks (for example, the clock RDQS_T and the clock RDQS_C). For example, referring to FIG. 8, the clock RDQS_T and the clock RDQS_C may be input to an input port (0, 1) of the multiplexer 820-1, and the clock RDQS_T and the clock RDQS_C may be input to an input port (1, 0) of the multiplexer 820-2.

For example, in the unflip path, each of the multiplexers 820-1 and 820-2 may receive the clock RDQS_T and the clock RDQS_C as an input signal, and in response to the control signal CTRL_MUX, the multiplexer 820-1 may select the clock RDQS_T to output the clock RDQS_T to the low pass filter 830-1, and the multiplexer 820-2 may select the clock RDQS_C to output the clock RDQS_C to the low pass filter 830-2.

Likewise, in the flip path, each of the multiplexers 820-1 and 820-2 may receive the clock RDQS_T and the clock RDQS_C as an input signal, and in response to the control signal CTRL_MUX, the multiplexer 820-1 may select the clock RDQS_C to output the clock RDQS_C to the low pass filter 830-1, and the multiplexer 820-2 may select the clock RDQS_T to output the clock RDQS_T to the low pass filter 830-2.

Each of the low pass filters 830-1 and 830-2 may convert a duty ratio of a selected clock, which is an input signal, into a direct current (DC) voltage. For example, when a source voltage is 1 V, each of the low pass filters 830-1 and 830-2 may convert a clock having a duty ratio of 50% into 0.5 V and may convert a clock having a duty ratio of 60% into 0.6 V. That is, each of the low pass filters 830-1 and 830-2 may provide the comparator 840 with a DC voltage corresponding to a duty ratio of a selected clock.

According to an embodiment, the flip path and the unflip may be symmetrical with each other, and the comparator 840 may compare an output voltage of each path, and thus, the read clock path skew monitoring module 133_1 may remove an offset thereof.

The read monitoring control module 810 may output the control signal CTRL_MUX, and thus, may select output signals of the multiplexers 820-1 and 820-2.

In an embodiment, the read monitoring control module 810 may output the control signal CTRL_MUX so that the multiplexers 820-1 and 820-2 output different clocks. For example, the read monitoring control module 810 may output the control signal CTRL_MUX so that the multiplexer 820-1 outputs the clock RDQS_T, and the multiplexer 820-2 outputs the clock RDQS_C. Also, the read monitoring control module 810 may output the control signal CTRL_MUX so that the multiplexer 820-1 outputs the clock RDQS_C, and the multiplexer 820-2 outputs the clock RDQS_T. The read monitoring control module 810 may control the output signals of the multiplexers 820-1 and 820-2, based on the control signal CTRL_MUX, and for example, the read monitoring control module 810 may be configured to output the clocks RDQS_T and RDQS_C in a pair of settings and output the clocks RDQS_C and RDQS_T in another pair of settings. In this case, the order of clock RDQS_T and clock RDQS_C may be alternately changed, or may be set to various combinations.

The comparator 840 may compare output values of two paths (for example, the unflip path and the flip path), and thus, may output a signal COMP_RD at a logic high level or a logic low level. The signal COMP_RD, which is an output signal, may have only one value among logic high (HIGH) and logic low (LOW).

The read monitoring control module 810 may receive the signal COMP_RD and may output the control signal CTRL_CAL, based on the signal COMP_RD, thereby controlling the read clock path skew calibration module 133_3.

In an embodiment, the read monitoring control module 810 may control the read clock path skew calibration module 133_3, based on a transition of the signal COMP_RD. In some embodiments, the read monitoring control module 810 may control the read clock path skew calibration module 133_3 to perform a delay addition operation until a logic state of the signal COMP_RD is shifted twice.

For example, the read monitoring control module 810 may provide the control signal CTRL_CAL to the read clock path skew calibration module 133_3 so that the read clock path skew calibration module 133_3 adds a delay to clocks (for example, all or some of a clock WDQS_I, a clock WDQS_Q, a clock WDQS_IB, and a clock WDQS_QB) until a logic state of the signal COMP_RD is shifted, and a shifted logic state is re-shifted.

For example, an example may be described where an output of the low pass filter 830-1 on the clock RDQS_T is 0.4 V, and an output of the low pass filter 830-2 on the clock RDQS_C is 0.6 V, and thus, the signal COMP_RD, which is an output of the comparator 840, is logic low (LOW), in the unflip path. In a state where the multiplexers 820-1 and 820-2 are set to the unflip path, after an operation of adding a series of delays to the clock WDQS_I or the clock WDQS_IB, an output of the low pass filter 830-1 on the clock RDQS_T may be 0.51 V, and an output of the low pass filter 830-2 on the clock RDQS_C may be 0.49 V, and thus, the signal COMP_RD, which is the output of the comparator 840, may be shifted to logic high (HIGH). Subsequently, in response to the control signal CTRL_MUX, the multiplexers 820-1 and 820-2 may be configured as the flip path. Here, based on an analog factor such as path asymmetry or a circuit offset, an output of the low pass filter 830-1 on the clock RDQS_C may be greater than 0.5 V, and an output of the low pass filter 830-2 on the clock RDQS_T may be less than 0.5 V, and thus, the signal COMP_RD may still be maintained logic high (HIGH). Subsequently, an operation of adding a series of delays to the clock WDQS_I or the clock WDQS_IB in the flip path may be repeated, an output of the low pass filter 830-1 on the clock RDQS_C may be 0.49 V, and an output of the low pass filter 830-2 on the clock RDQS_T may be 0.51 V, and thus, it may be considered that a delay addition operation (i.e., skew calibration) on the clock WDQS_I or the clock WDQS_IB is completed at the time at which the signal COMP_RD, which is the output of the comparator 840, is re-shifted to logic low (LOW).

Also, the read clock path skew calibration module 133_3 may determine whether a delay addition operation on four clocks (for example, a clock WDQS_I, a clock WDQS_Q, a clock WDQS_IB, and a clock WDQS_QB) is completed, based on an output signal (for example, the signal COMP_RD) of the comparator 840, and when the delay addition operation is completed, the read monitoring control module 810 may provide a read delay code (RD DELAY CODE) to the output circuit 137.

Also, as described above with reference to FIG. 7, in some embodiments, an order in which a delay is added to clocks may be predetermined, and for example, the read clock path skew calibration module 133_3 may add a delay to each paired clocks in the order of a pair of clock WDQS_I and clock WDQS_IB, a pair of clock WDQS_Q and clock WDQS_QB, and a pair of clock WDQS_I and clock WDQS_Q.

In this context, an example may be described where skew calibration on an output signal of a relay path of an RDQS signal starts, and a logic state of an initial signal COMP_RD is logic low (LOW) in the unflip path.

First, the read monitoring control module 810 may provide the control signal CTRL_CAL to the read clock path skew calibration module 133_3 so that the read clock path skew calibration module 133_3 first adds a delay to the clock WDQS_I and the clock WDQS_IB until the signal COMP_RD received in the unflip path is shifted from logic low (LOW) to logic high (HIGH), and then, is re-shifted from logic high (HIGH) to logic low (LOW) in the flip path. Here, it may be considered that a delay addition operation on the clock WDQS_I and the clock WDQS_IB is completed at the time at which a shifted logic state of the signal COMP_RD is re-shifted (logic low (LOW)->logic high (HIGH) ->logic low (LOW)).

Subsequently, the read monitoring control module 810 may provide the control signal CTRL_CAL to the read clock path skew calibration module 133_3 so that the read clock path skew calibration module 133_3 adds a delay to the clock WDQS_Q and the clock WDQS_QB until the signal COMP_RD received in the unflip path is shifted from logic low (LOW) to logic high (HIGH), and then, is re-shifted from logic high (HIGH) to logic low (LOW) in the flip path. Here, it may be considered that a delay addition operation on the clock WDQS_Q and the clock WDQS_QB is completed at the time at which a shifted logic state of the signal COMP_RD is re-shifted (logic low (LOW)->logic high (HIGH)->logic low (LOW)).

Subsequently, the read monitoring control module 810 may provide the control signal CTRL_CAL to the read clock path skew calibration module 133_3 so that the read clock path skew calibration module 133_3 adds a delay to the clock WDQS_I and the clock WDQS_Q until the signal COMP_RD received in the unflip path is shifted from logic low (LOW) to logic high (HIGH), and then, is re-shifted from logic high (HIGH) to logic low (LOW) in the flip path. Here, it may be considered that a delay addition operation on the clock WDQS_I and the clock WDQS_Q is completed at the time at which a shifted logic state of the signal COMP_RD is re-shifted (logic low (LOW)->logic high (HIGH)->logic low (LOW)).

Here, it may be considered that a delay addition operation on the four clocks (for example, the clock WDQS_I, the clock WDQS_Q, the clock WDQS_IB, and the clock WDQS_QB) is completed. At this time, the read monitoring control module 810 may provide a read delay code (RD DELAY CODE) to the output circuit 137. That is, when delay addition on all clock pairs is completed, the read monitoring control module 810 may provide the read delay code (RD DELAY CODE) to the output circuit 137.

Here, the read delay code (RD DELAY CODE) may be a set of delay calibration values of a delay cell corresponding to a pair of clock WDQS_I and clock WDQS_IB, a pair of clock WDQS_Q and clock WDQS_QB, and a pair of clock WDQS_I and clock WDQS_Q. In some embodiments, the read delay code (RD DELAY CODE) may consist of 4 bits (total 12 bits) for each clock pair, and each 4 bits may be a digital code representing a duty value (or a delay calibration value) obtained by converting skew calibration information for each clock pair.

That is, the read clock path skew calibration module 133_3 may determine whether a delay addition operation on the four clocks (for example, the clock WDQS_I, the clock WDQS_Q, the clock WDQS_IB, and the clock WDQS_QB) is completed, based on the number of transitions of the signal COMP_RD, which is an output of the comparator 840, and when the delay addition operation is completed, the read monitoring control module 810 may provide a read delay code (RD DELAY CODE) to the output circuit 137. In the embodiment described above, when the signal COMP_RD is shifted six times, it may be considered that a delay addition operation on the four clocks (for example, the clock WDQS_I, the clock WDQS_Q, the clock WDQS_IB, and the clock WDQS_QB) is completed.

FIG. 9 is a block diagram for describing an implementation embodiment of the write clock path skew monitoring module of FIGS. 6 and 7.

Referring to FIG. 9, a write clock path skew monitoring module 135_1 may include a write monitoring control module 910, multiplexers 920-1 and 920-2, low pass filters 930-1 and 930-2, a comparator 940, and clock serializers 950-1 and 950-2.

Unlike the read clock path skew monitoring module 133_1 described above with reference to FIG. 8, a WDQS signal may be provided to the write clock path skew monitoring module 135_1 in the form of a four-phase clock. That is, the WDQS signal may include four digital clocks I, Q, IB, and QB each having a 90-degree phase difference therebetween, and the four digital clocks I, Q, IB, and QB may be respectively input to four lines. To serialize and process corresponding clock phases, the write clock path skew monitoring module 135_1 may further include clock serializers 950-1 and 950-2.

Furthermore, the write monitoring control module 910, the multiplexers 920-1 and 920-2, the low pass filters 930-1 and 930-2, and the comparator 940 of FIG. 9 may respectively perform operations similar to those of the read monitoring control module 810, the multiplexers 820-1 and 820-2, the low pass filters 830-1 and 830-2, and the comparator 840 of FIG. 8, and thus, repeated descriptions are omitted, and differences therebetween will be mainly described below.

The write clock path skew monitoring module 135_1 may receive four clocks (for example, a clock WDQS_I, a clock WDQS_Q, a clock WDQS_IB, and a clock WDQS_QB), may output a control signal CTRL_CAL to a write clock path skew calibration module 135_3, based on a monitoring result (for example, a signal COMP_RD), and may output a final monitoring result (for example, a write delay code (WR DELAY CODE)) to an output module 137.

Referring to FIG. 9, it is illustrated that the write clock path skew monitoring module 135_1 may receive the four clocks in the order of the clock WDQS_I, the clock WDQS_Q, the clock WDQS_IB, and the clock WDQS_QB or the order of the clock WDQS_Q, the clock WDQS_IB, the clock WDQS_QB, and the clock WDQS_I, but the present disclosure is not limited thereto. A WDQS signal applied to the four lines in the order of the clock WDQS_I, the clock WDQS_Q, the clock WDQS_IB, and the clock WDQS_QB may be referred to as a “WDQS (I, Q, IB, and QB) signal”, and a WDQS signal applied to the four lines in the order of the clock WDQS_Q, the clock WDQS_IB, the clock WDQS_QB, and the clock WDQS_I may be referred to as a “WDQS (Q, IB, QB, and I) signal”.

The multiplexers 920-1 and 920-2 may receive the WDQS (I, Q, IB, and QB) signal and the WDQS (Q, IB, QB, and I) signal as an input signal. For example, referring to FIG. 9, input ports (0, 1) of the multiplexers 920-1 and 920-2 may be respectively connected to four clock lines. Here, a total of four clock lines may be input to the input port (0) of the multiplexer 920-1 and the input port (1) of the multiplexer 920-2 in the order of the clock WDQS_I line, the clock WDQS_Q line, the clock WDQS_IB line, and the clock WDQS_QB line. Also, a total of four clock lines may be input to the input port (1) of the multiplexer 920-1 and the input port (0) of the multiplexer 920-2 in the order of the clock WDQS_Q line, the clock WDQS_IB line, the clock WDQS_QB line, and the clock WDQS_I line.

The multiplexer 920-1 may select one signal from among the WDQS (I, Q, IB, and QB) signal and the WDQS (Q, IB, QB, and I) signal to output the selected signal to the clock serializer 950-1, in response to a control signal CTRL_MUX. Likewise, the multiplexer 920-2 may select one signal from among the WDQS (Q, IB, QB, and I) signal and the WDQS (I, Q, IB, and QB) signal to output the selected signal to the clock serializer 950-2, in response to the control signal CTRL_MUX.

In response to a control signal CTRL_SERIAL of the write monitoring control module 910, each of the clock serializers 950-1 and 950-2 may serialize selected WDQS signals to convert into a single clock stream, and then, the single clock stream may be transferred to the low pass filters 930-1 and 930-2 and may be converted into a duty-based DC voltage. Subsequently, each of the low pass filters 930-1 and 930-2 may provide the duty-based DC voltage to the comparator 940.

According to an embodiment, the flip path and the unflip may be symmetrical with each other, and the comparator 940 may compare an output voltage of each path, and thus, the write clock path skew monitoring module 135_1 may remove an offset thereof.

The write monitoring control module 910 may output the control signal CTRL_MUX, and thus, may select output signals of the multiplexers 920-1 and 920-2. Also, the write monitoring control module 910 may output the control signal CTRL_MUX and/or the control signal CTRL_SERIAL and may thus select output signals of the clock serializers 950-1 and 950-2.

For example, in order to monitor a skew between the clock WDQS_I and the clock WDQS_IB, the write monitoring control module 910 may perform control so that each of the WDQS (Q, IB, QB, and I) signal and the WDQS (I, Q, IB, and QB) signal is selected by the multiplexers 920-1 and 920-2, based on the control signal CTRL_MUX. Also, the write monitoring control module 910 may perform control so that each of the clock serializers 950-1 and 950-2 serializes the clock WDQS_I and the clock WDQS_IB, based on the control signal CTRL_SERIAL.

That is, the output signals of the clock serializers 950-1 and 950-2 may be to be monitored, and based on the control signal CTRL_MUX and the control signal CTRL_SERIAL, two of the four clocks (for example, the clock WDQS_I, the clock WDQS_Q, the clock WDQS_IB, and the clock WDQS_QB) may be set to be monitored.

Moreover, as described above with reference to FIG. 7, in some embodiments, a monitoring order (or an order in which a delay is added to clocks) may be predetermined, and for example, the write clock path skew calibration module 135_3 may perform monitoring on each paired clocks in the order of a pair of clock WDQS_I and clock WDQS_IB, a pair of clock WDQS_Q and clock WDQS_QB, and a pair of clock WDQS_I and clock WDQS_Q, and thus, the write clock path skew calibration module 135_3 may also add a delay to each of corresponding two clocks in the same order.

In this context, the write monitoring control module 910 may output the control signal CTRL_MUX and/or the control signal CTRL_SERIAL so that outputs of the clock serializers 950-1 and 950-2 are based on a predetermined monitoring order. For example, the write monitoring control module 910 may output the control signal CTRL_MUX and/or the control signal CTRL_SERIAL so that the outputs of the clock serializers 950-1 and 950-2 are based on the order of a pair of clock WDQS_I and clock WDQS_IB, a pair of clock WDQS_Q and clock WDQS_QB, and a pair of clock WDQS_I and clock WDQS_Q. That is, the order of monitoring targets may be the order of a pair of clock WDQS_I and clock WDQS_IB, a pair of clock WDQS_Q and clock WDQS_QB, and a pair of clock WDQS_I and clock WDQS_Q.

In an embodiment, similarly to the read monitoring control module 810, the write monitoring control module 910 may control the write clock path skew calibration module 135_3, based on a transition of a signal COMP_WR. In some embodiments, the write monitoring control module 910 may control the write clock path skew calibration module 135_3 so that a delay addition operation is performed until a logic state of the signal COMP_WR is shifted twice (for example, the order of unflip path and flip path, or the order of flip path and unflip path). That is, the flip path and the unflip may be symmetrical with each other, and the comparator 940 may compare an output voltage of each path, and thus, the write clock path skew monitoring module 135_1 may remove an offset thereof.

Also, the write clock path skew calibration module 135_3 may determine whether a delay addition operation on the four clocks (for example, the clock WDQS_I, the clock WDQS_Q, the clock WDQS_IB, and the clock WDQS_QB) is completed, based on an output signal (for example, the signal COMP_WR) of the comparator 940, and when the delay addition operation is completed, the write monitoring control module 910 may provide a write delay code (WR DELAY CODE) to the output circuit 137.

In some embodiments, the write delay code (WR DELAY CODE) may consist of 4 bits (a total of 12 bits) for each clock pair (for example, a pair of clock WDQS_I and clock WDQS_IB, a pair of clock WDQS_Q and clock WDQS_QB, and a pair of clock WDQS_I and clock WDQS_Q), and each 4 bits may be a digital code representing a duty value (or a delay calibration value) obtained by converting skew calibration information for each clock pair.

In some embodiments, the write clock path skew calibration module 135_3 may determine whether a delay addition operation on the four clocks (for example, the clock WDQS_I, the clock WDQS_Q, the clock WDQS_IB, and the clock WDQS_QB) is completed, based on the number of transitions of the signal COMP_WR which is an output of the comparator 940, and when the delay addition operation is completed, the write monitoring control module 910 may provide the write delay code (WR DELAY CODE) to the output circuit 137. For example, as in the embodiment of the read clock path skew calibration module 133_3 described above, when the signal COMP_WR is shifted six times, it may be considered that a delay addition operation on the four clocks (for example, the clock WDQS_I, the clock WDQS_Q, the clock WDQS_IB, and the clock WDQS_QB) is completed.

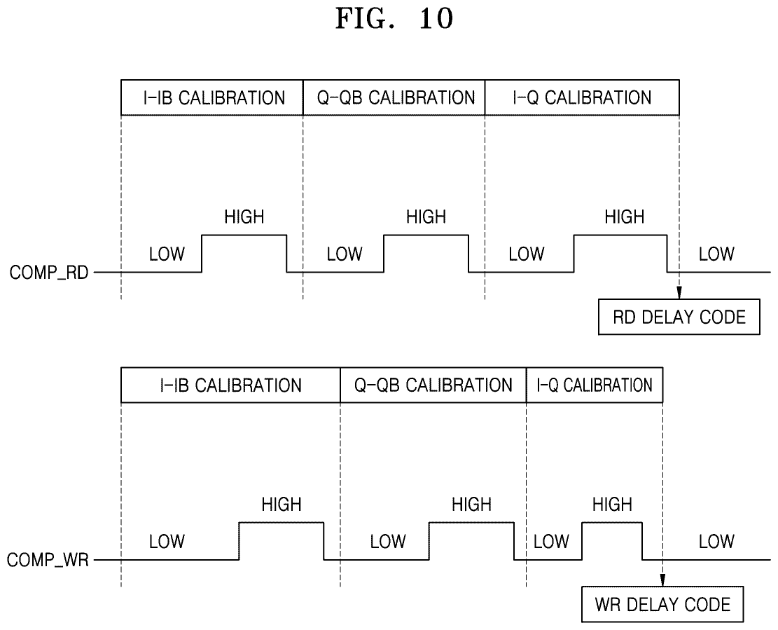

FIG. 10 is a timing diagram of the comparators of FIGS. 8 and 9 according to an embodiment.

In an embodiment, as described above with reference to FIGS. 8 and 9, referring to FIG. 10, when a signal COMP_RD is shifted six times, it may be considered that a delay addition operation on four clocks (for example, a clock WDQS_I, a clock WDQS_Q, a clock WDQS_IB, and a clock WDQS_QB) relayed in a read clock path is completed. Also, when a signal COMP_WR is shifted six times, it may be considered that a delay addition operation on four clocks (for example, a clock WDQS_I, a clock WDQS_Q, a clock WDQS_IB, and a clock WDQS_QB) relayed in a write clock path is completed.

Here, a monitoring order (or an order in which a delay is added to clocks) may be predetermined, and referring to FIG. 10, monitoring (or adding a delay to clocks) may be performed on each paired clocks in the order of a pair of clock WDQS_I and clock WDQS_IB, a pair of clock WDQS_Q and clock WDQS_QB, and a pair of clock WDQS_I and clock WDQS_Q.

Also, the read clock path skew monitoring module 133_1 may determine a case, where the signal COMP_RD has been shifted six times, as a case where skew calibration on a read clock path is completed, and then, a determination result may be provided to the output module 137 in the form of read delay code (RD DELAY CODE).

Also, the write clock path skew monitoring module 135_1 may determine a case, where the signal COMP_WR has been shifted six times, as a case where skew calibration on a write clock path is completed, and then, a determination result may be provided to the output module 137 in the form of write delay code (WR DELAY CODE).

As described above, in a wafer-level test, the memory device 20 according to an embodiment may independently perform skew calibration for each clock path, may independently determine skew calibration completion for each clock path with respect to the number of transitions of the comparator signals COMP_RD and COMP_WR, and may output a corresponding delay code. Such a structure may contribute to increase a timing precision of a memory signal path. Also, a defect of an IO interface may be early detected in a wafer test operation, and thus, a wafer yield may be enhanced. That is, the reliability and yield of the memory device 20 may be simultaneously enhanced.

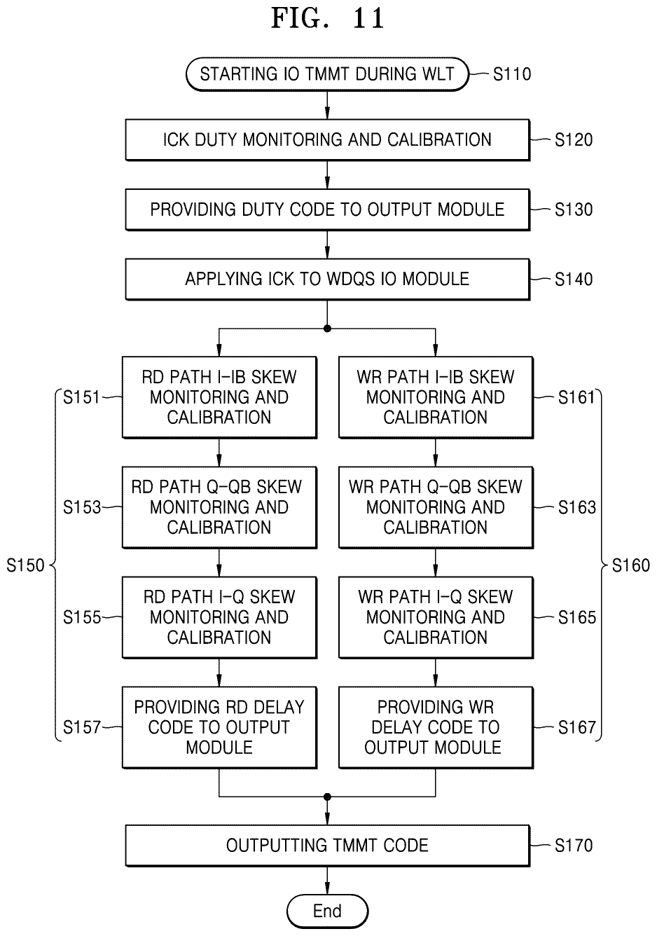

FIG. 11 is a flowchart illustrating an operating method of a memory device, according to an embodiment. The operating method according to an embodiment illustrated in FIG. 11 may be performed in the DWORD module 100 of FIG. 3. FIG. 11 may be described with reference to FIGS. 1 to 10.

In operation S110, in a wafer-level test, the DWORD module 100 may start to perform an IO TMMT. For example, in the wafer-level test, the DWORD module 100 may start to perform the IO TMMT in response to a signal (IO TMMT START) of the test module 30.

In operation S120, the internal clock generator 131_1 of the DWORD module 100 may generate an internal clock ICK, and duty monitoring and calibration may be performed on the internal clock ICK generated by the duty monitoring module 131_3 and the duty calibration module 131_5. Here, as a result of performance of the duty monitoring and calibration, a duty ratio of the internal clock ICK may be calibrated to approximately be 50:50.

In operation S130, after the duty monitoring and calibration on the internal clock ICK is completed, the duty monitoring module 131_3 may provide a final monitoring result to the output module 137 in the form of duty code (DUTY CODE).

In operation S140, the internal clock ICK may be applied to the pin WDQS_T and the pin WDQS_C of the WDQS IO module 123. For example, the WDQS IO module 123 may apply a clock WDQS_I, a clock WDQS_Q, a clock WDQS_IB, and a clock WDQS_QB to a read clock path and a write clock path in the form of a four-phase clock, based on an internal clock ICK_T received through the pin WDQS_T and an internal clock ICK_C received through the pin WDQS_C.

After operation S140, operation S150 and operation S160 may be performed in parallel.

In operation S150, skew monitoring and calibration may be performed on the read clock path by the read clock path skew monitoring module 133_1 and the read clock path skew calibration module 133_3.

Operation S150 may include operation S151, operation S153, operation S155, and operation S157.

In operation S151, skew monitoring and calibration may be performed on the clock WDQS_I and/or the clock WDQS_IB relayed in the read clock path by using the read clock path skew monitoring module 133_1 and the read clock path skew calibration module 133_3.

In operation S153, skew monitoring and calibration may be performed on the clock WDQS_Q and/or the clock WDQS_QB relayed in the read clock path by using the read clock path skew monitoring module 133_1 and the read clock path skew calibration module 133_3.

In operation S155, skew monitoring and calibration may be performed on the clock WDQS_I and/or the clock WDQS_Q relayed in the read clock path by using the read clock path skew monitoring module 133_1 and the read clock path skew calibration module 133_3.

In operation S157, after skew monitoring and calibration on four clocks WDQS_I, WDQS_Q, WDQS_IB, and WDQS_QB relayed in the read clock path are completed, the read clock path skew monitoring module 133_1 may provide a final monitoring result to the output module 137 in the form of read delay code (RD DELAY CODE).

In operation S160, skew monitoring and calibration may be performed on the write clock path by the write clock path skew monitoring module 135_1 and the write clock path skew calibration module 135_3.

Operation S160 may include operation S161, operation S163, operation S165, and operation S167.

In operation S161, skew monitoring and calibration may be performed on the clock WDQS_I and/or the clock WDQS_IB relayed in the write clock path by using the write clock path skew monitoring module 135_1 and the write clock path skew calibration module 135_3.

In operation S163, skew monitoring and calibration may be performed on the clock WDQS_Q and/or the clock WDQS_QB relayed in the write clock path by using the write clock path skew monitoring module 135_1 and the write clock path skew calibration module 135_3.

In operation S165, skew monitoring and calibration may be performed on the clock WDQS_I and/or the clock WDQS_Q relayed in the write clock path by using the write clock path skew monitoring module 135_1 and the write clock path skew calibration module 135_3.

In operation S157, after skew monitoring and calibration on four clocks WDQS_I, WDQS_Q, WDQS_IB, and WDQS_QB relayed in the write clock path are completed, the write clock path skew monitoring module 135_1 may provide a final monitoring result to the output module 137 in the form of write delay code (WR DELAY CODE).

In operation S170, the output module 137 may output the TMMT code (TMMT CODE). As a result of operation S140, the output module 137 may receive the duty code (DUTY CODE). Furthermore, as a result of operation S150 and operation S160, when the output module 137 further receives the read delay code (RD DELAY CODE) and the write delay code (WR DELAY CODE), the output module 137 may group the duty code (DUTY CODE), the read delay code (RD DELAY CODE), and the write delay code (WR DELAY CODE), and thus, may output the TMMT code (TMMT CODE). For example, the output module 137 may output the TMMT code (TMMT CODE) to an external device (for example, the test module 30 of FIG. 3).

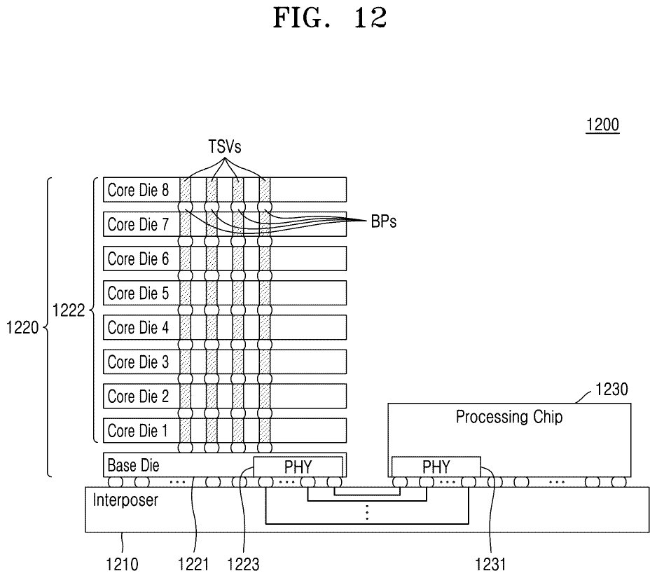

FIGS. 12 to 14 are diagrams illustrating examples of a semiconductor package according to embodiments.

Referring to FIG. 12, a semiconductor package 1200 may include an interposer 1210, a memory device 1220, and a processing chip 1230. The semiconductor package 1200 may further include a substrate (not shown) disposed under the interposer 1210.

The interposer 1210 may include signal lines connecting the memory device 1220 to the processing chip 1230. For example, the interposer 1210 may provide physical paths including conductive materials for electrically connecting a physical region 1223 of the memory device 1220 to a physical region 1231 of the processing chip 1230.

The memory device 1220 may be stacked on the interposer 1210. The memory device 1220 may include a base die 1221 and a plurality of core dies 1222. The memory device 1220 may have a test structure where test equipment may perform a high-speed test in a chip-on wafer state before packaging. In FIG. 12, the number of core dies 1222 is illustrated as eight, but the present disclosure is not limited to the illustration of FIG. 12. The base die 1221 may be electrically connected to the interposer 1210 through a plurality of micro bumps BPs. The base die 1221 may include the physical region 1223. The plurality of core dies 1222 may be stacked on the base die 1221, a plurality of TSVs TSVs may be formed to pass through the plurality of core dies 1222, and the plurality of micro bumps BPs electrically connecting the plurality of TSVs TSVs with each other may be disposed between the plurality of core dies 1222. The plurality of TSVs TSVs and the plurality of micro bumps BPs may provide electrical and physical paths between the base die 1221 and the plurality of core dies 1222. The memory device 1220 may correspond to the memory device 20 of FIG. 1, and the embodiments described above with reference to FIGS. 1 to 11 may be applied to the memory device 1220.

The processing chip 1230 may correspond to a processor such as an SoC, a GPU, or a CPU. The processing chip 1230 may include the physical region 1231 which is electrically connected to the physical region 1223 of the base die 1221 through the interposer 1210. The physical region 1231 of the processing chip 1230 may be electrically connected to the physical region 1223 of the base die 1221 and may transfer or receive a data signal to or from the physical region 1223 of the base die 1221.

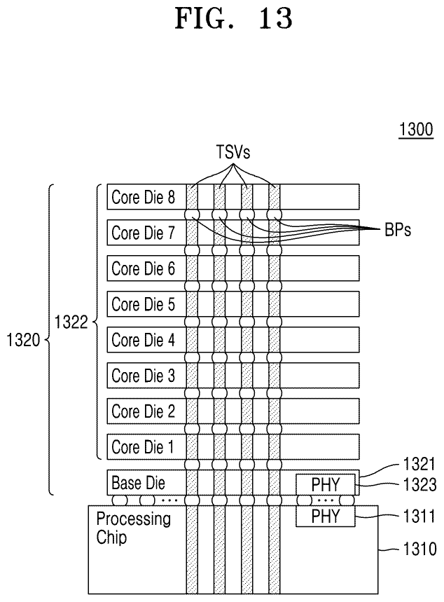

Referring to FIG. 13, a semiconductor package 1300 may include a processing chip 1310 and a memory device 1320 stacked on the processing chip 1310. The memory device 1320 may include a base die 1321 and a plurality of core dies 1322. The memory device 1320 may have a structure where a tester may perform a high-speed test in a chip-on wafer state. A physical region 1311 of the processing chip 1310 and a physical region 1323 of the base die 1321 may be electrically connected to each other through a plurality of micro bumps BPs. The processing chip 1310 may further include a plurality of TSVs TSVs which are used to electrically connect the memory device 1320 to the processing chip 1310, and the plurality of TSVs TSVs may be formed to pass through the processing chip 1310. The semiconductor package 1300 may further include an interposer (not shown) disposed on one surface of the processing chip 1310 (for example, a lower portion of the processing chip 1310) and a substrate (not shown) disposed on one surface of an interposer (for example, a lower portion of the interposer). The memory device 1320 may correspond to the memory device 20 of FIG. 1, and the embodiments described above with reference to FIGS. 1 to 11 may be applied to the memory device 1320.

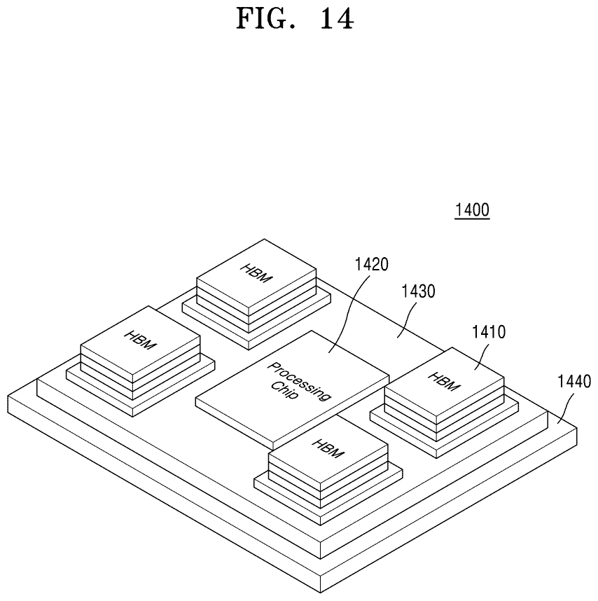

Referring to FIG. 14, a semiconductor package 1400 may include a plurality of HBMs 1410, a processing chip 1420, an interposer 1430, and a substrate 1440. The semiconductor package 1400 may be used in data processing, and for example, the semiconductor package 1400 may be used in a neural network operation. A hardware accelerator included in the semiconductor package 1400 may perform a neural network operation using data and a weight, and the plurality of HBMs 1410 may store the data and the weight, based on control by the hardware accelerator. Each of the plurality of HBMs 1410 may correspond to the memory device 20 of FIG. 1, and the embodiments described above with reference to FIGS. 1 to 11 may be applied to each of the plurality of HBMs 1410.

The plurality of HBMs 1410 may have a test structure where test equipment may perform a high-speed test in a chip-on wafer state before packaging. Here, according to an embodiment, in a wafer-level test, skew calibration may be independently performed for each clock path, and as a result of skew calibration independently performed for each clock path, a corresponding delay code may be obtained. Such a structure may contribute to increase a timing precision of a memory signal path. Also, a defect of an IO interface may be early detected in a wafer test operation, and thus, a wafer yield may be enhanced. That is, the reliability and yield of the plurality of HBMs 1410 may be simultaneously enhanced.

The interposer 1430 may be disposed on the substrate 1440, each of the plurality of HBMs 1410 and the processing chip 1420 may be disposed on the interposer 1430, and the plurality of HBMs 1410 may be stacked on the interposer 1430. According to an embodiment, the plurality of HBMs 1410 may perform operation processing. The processing chip 1420 may be implemented as a CPU or a hardware accelerator such as a GPU, a field-programmable gate array (FPGA), a massively parallel processor array (MPPA), an application-specific integrated circuit (ASIC), a neural processing unit (NPU), a tensor processing unit (TPU), or a multi-processor system-on-chip (MPSoC). The processing chip 1420 may communicate with the plurality of HBMs 1410 through physical regions. In another embodiment, the processing chip 1420 may be omitted in the semiconductor package 1400.

It is obvious to those of ordinary skill in the art that a structure of the inventive concept may be variously corrected or modified without departing from the spirit and scope of the inventive concept. If the correction and modification of the inventive concept are within a range of claims and equivalent embodiments, it is construed that the inventive concept includes the modification and correction thereof.

Hereinabove, exemplary embodiments have been described in the drawings and the specification. Embodiments have been described by using the terms described herein, but this has been merely used for describing the inventive concept and has not been used for limiting a meaning or limiting the scope of the inventive concept defined in the following claims. Therefore, it may be understood by those of ordinary skill in the art that various modifications and other equivalent embodiments may be implemented from the inventive concept. Accordingly, the spirit and scope of the inventive concept may be defined based on the spirit and scope of the following claims.

While the inventive concept has been particularly shown and described with reference to embodiments thereof, it will be understood that various changes in form and details may be made therein without departing from the spirit and scope of the following claims.

What is claimed is:

1. A memory device comprising:
a memory cell array;
an input/output (IO) module including a write clock path and a read clock path; and
an IO built-in self-test (BIST) (IO BIST) device,
wherein the IO BIST device is configured to, in a wafer-level test of the memory device, monitor a clock skew of each of the write clock path and the read clock path and calibrate a corresponding clock skew, based on a monitoring result.

2. The memory device of claim 1, wherein the IO BIST device is further configured to output a digital code corresponding to a final monitoring result.

3. The memory device of claim 2, wherein the digital code comprises calibration information about a duty cycle of an internal clock, calibration information about the clock skew of the read clock path, or calibration information about the clock skew of the write clock path.

4. The memory device of claim 1, wherein the IO BIST device further comprises an internal clock generation module configured to generate an internal clock,
the IO module further comprises a WDQS IO module including a WDQS pin, and
the IO BIST device is further configured to apply the internal clock to the WDQS pin.

5. The memory device of claim 4, wherein the IO BIST device is further configured to, before applying the internal clock to the WDQS pin, monitor a duty cycle of the internal clock and calibrate the duty cycle of the internal clock, based on a monitoring result.

6. The memory device of claim 4, wherein the WDQS IO module is further configured to generate a WDQS signal and provide the generated WDQS signal to each of the read clock path and the write clock path, based on the internal clock.

7. The memory device of claim 6, wherein the IO BIST device is further configured to monitor a clock skew of the read clock path, based on the WDQS signal, and calibrate the clock skew of the read clock path, based on a monitoring result.

8. The memory device of claim 7, wherein the IO BIST device is further configured to monitor the clock skew of the read clock path in a predetermined order and calibrate the clock skew of the read clock path, based on a monitoring result.

9. The memory device of claim 8, wherein the IO BIST device is further configured to calibrate each of two clock pairs among four clocks corresponding to the WDQS signal relayed in the read clock path,
the predetermined order is performed in an order in which a pair of a first clock and a third clock are first calibrated, a pair of a second clock and a fourth clock are calibrated subsequently, and the pair of the first clock and the third clock are calibrated subsequently, and
the four clocks each are configured to have a 90-degree phase difference in the order of the first clock, the second clock, the third clock, and the fourth clock.

10. The memory device of claim 6, wherein the IO BIST device is further configured to monitor a clock skew of the write clock path, based on the WDQS signal, and calibrate the clock skew of the write clock path, based on a monitoring result.

11. The memory device of claim 10, wherein the IO BIST device is further configured to monitor the clock skew of the write clock path in a predetermined order and calibrate the clock skew of the write clock path, based on a monitoring result.

12. The memory device of claim 11, wherein the IO BIST device is further configured to calibrate each of two clock pairs among four clocks corresponding to the WDQS signal relayed in the write clock path,
the predetermined order is performed in an order in which a pair of a first clock and a third clock are first calibrated, a pair of a second clock and a fourth clock are calibrated subsequently, and the pair of the first clock and the third clock are calibrated subsequently, and
the four clocks each are configured to have a 90-degree phase difference in the order of the first clock, the second clock, the third clock, and the fourth clock.

13. The memory device of claim 1, wherein the read clock path comprises a path up to an RDQS pin of an RDQS IO module from a read clock path circuit relaying an RDQS signal.

14. The memory device of claim 1, wherein the write clock path comprises a write clock path circuit configured to relay a WDQS signal.

15. A memory device including a base die, the base die comprising:
a plurality of per-channel input/output (IO) modules,
wherein each of the plurality of per-channel IO modules comprises a plurality of DWORD modules,
wherein a first DWORD module among the plurality of DWORD modules comprises:
an IO module including a write clock path and a read clock path for a memory cell array; and
an IO built-in self-test (BIST) (IO BIST) device, and
wherein the IO BIST device is configured to, in a wafer-level test of a memory die including the first DWORD module, monitor a clock skew of each of the write clock path and the read clock path and calibrate a corresponding clock skew, based on a monitoring result.

16. The memory device of claim 15, wherein the IO BIST device is further configured to output a digital code corresponding to a final monitoring result.

17. The memory device of claim 16, wherein the digital code comprises calibration information about a duty cycle of an internal clock, calibration information about the clock skew of the read clock path, or calibration information about the clock skew of the write clock path.

18. The memory device of claim 15, wherein the IO BIST device further comprises an internal clock generation module configured to generate an internal clock,
the IO module further comprises a WDQS IO module including a WDQS pin, and
the IO BIST device is further configured to apply the internal clock to the WDQS pin.

19. The memory device of claim 18, wherein the IO BIST device is further configured to, before applying the internal clock to the WDQS pin, monitor a duty cycle of the internal clock and calibrate the duty cycle of the internal clock, based on a monitoring result.

20. A wafer-level testing method for semiconductor chip, the wafer-level testing method comprising:
receiving a start signal of a timing margin measurement test (TMMT) from a test module; and
monitoring, by using an input/output built-in self-test (IO BIST) device included in a target wafer of the semiconductor chip, a clock skew of each of a write clock path and a read clock path, calibrating a corresponding clock skew, based on a monitoring result, and outputting a digital code corresponding to a final monitoring result, in response to the start signal.
